(19) United States
(12) Patent Application Publication
(10) Pub. No.: US 2026/0349192 A1
(43) Pub. Date: Nov. 5, 2026

(54) PACKAGE STRUCTURE AND OPTICAL GUIDING ELEMENT

(71) Applicant: Advanced Semiconductor Engineering, Inc., Kaohsiung (TW)

(72) Inventors: Pei-Jung YANG, Kaohsiung (TW); Chi-Han CHEN, Kaohsiung (TW); Chang-Yu LIN, Kaohsiung (TW); Hai-Ming CHEN, Kaohsiung (TW)

(73) Assignee: Advanced Semiconductor Engineering, Inc., Kaohsiung (TW)

(21) Appl. No.: 19/199,320

(22) Filed: May 5, 2025

(51) Int. Cl. G02B 6/42; H10W 40/22; H10W 70/63; H10W 90/00

(52) U.S. Cl. CPC G02B 6/4214; G02B 6/4206; G02B 6/4239; H10W 40/22; H10W 70/635; H10W 90/00; H10W 90/701; H10W 90/724

(57) ABSTRACT

A package structure and an optical guiding element are provided. The package structure includes a photonic component, an optical guiding component, and a connection structure. The optical guiding component is disposed external to the photonic component and is configured to change a transmission direction of an optical signal from the photonic component. The connection structure connects the optical guiding component to the photonic component and is configured to reduce scattering of the optical signal during transmission.

### BACKGROUND

### 1. Technical Field

The present disclosure relates generally to a package structure and an optical guiding element.

### 2. Description of the Related Art

Typically, a photonic component is usually optically coupled to optical fibers by edge coupling between the optical fibers and waveguides exposed at its edge. Therefore, it would be difficult to perform an optoelectronic inspection on a wafer-level photonic structure, which may be performed from above the wafer-level photonic structure instead of from edges thereof, unless a singulation operation is performed to expose the waveguides from edges of the singulated photonic structure. However, such process may increase the processing time and the costs.

### SUMMARY

In one or more arrangements, a package structure includes a photonic component, an optical guiding component, and a connection structure. The optical guiding component is disposed external to the photonic component and is configured to change a transmission direction of an optical signal from the photonic component. The connection structure connects the optical guiding component to the photonic component and is configured to reduce scattering of the optical signal during transmission.

In one or more arrangements, a package structure includes a photonic component, an optical guiding component, and an encapsulant. The photonic component includes an optical channel. The encapsulant encapsulates the photonic component and the optical guiding component. The optical guiding component is configured to direct an optical signal from the optical channel to transmit along an optical path embedded in the encapsulant and emit out of the encapsulant.

In one or more arrangements, an optical guiding element includes a reflective element. The reflective element is fixedly coupled to an optical channel of a photonic component via an integrated alignment structure. The optical guiding element is configured to redirect, concentrate, or diffuse an optical signal based on a predetermined distribution profile of the optical guiding element.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a top view of a package structure in accordance with some arrangements of the present disclosure.

FIG. 1B is a cross-section of a package structure in accordance with some arrangements of the present disclosure.

FIG. 1C is a top view of a package structure in accordance with some arrangements of the present disclosure.

FIG. 1D is a cross-section of a package structure in accordance with some arrangements of the present disclosure.

FIG. 1E is a perspective view of a portion of a package structure in accordance with some arrangements of the present disclosure.

FIG. 2A is a top view of a package structure in accordance with some arrangements of the present disclosure.

FIG. 2B is a cross-section of a package structure in accordance with some arrangements of the present disclosure.

FIG. 2C is a cross-section of a portion of a package structure in accordance with some arrangements of the present disclosure.

FIG. 2D is a top view of a package structure in accordance with some arrangements of the present disclosure.

FIG. 2E is a perspective view of a portion of a package structure in accordance with some arrangements of the present disclosure.

FIG. 3 is a cross-section of a package structure in accordance with some arrangements of the present disclosure.

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, and FIG. 4M illustrate various stages of an exemplary method for manufacturing a package structure in accordance with some embodiments of the present disclosure.

FIG. 5A, FIG. 5B, FIG. 5C, FIG. 5D, FIG. 5E, FIG. 5F, FIG. 5G, FIG. 5H, and FIG. 5I illustrate various stages of an exemplary method for manufacturing a package structure in accordance with some embodiments of the present disclosure.

FIG. 6A, FIG. 6B, FIG. 6C, FIG. 6D, FIG. 6E, and FIG. 6F illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

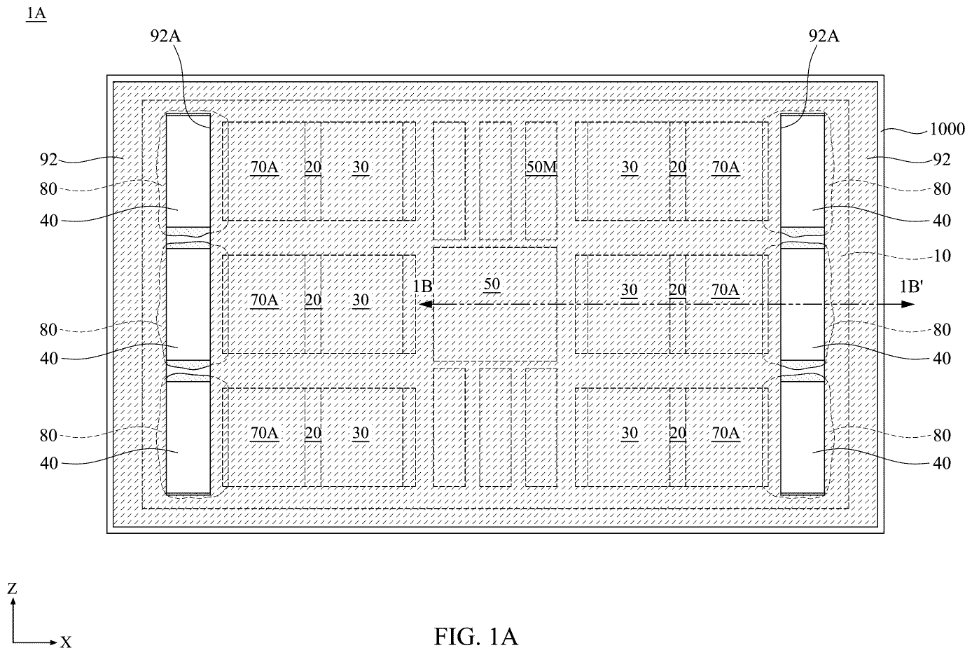

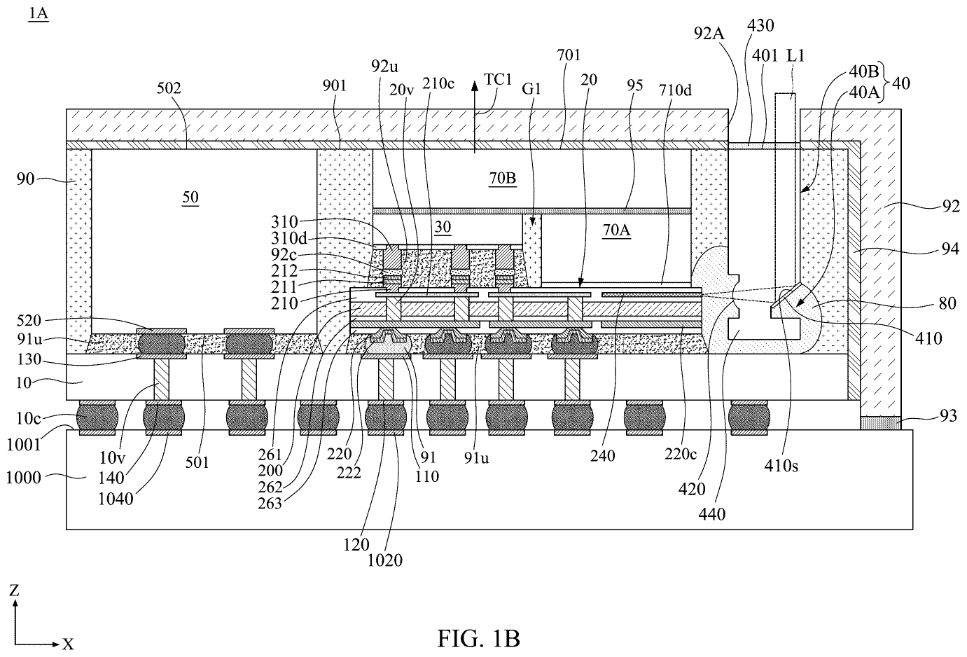

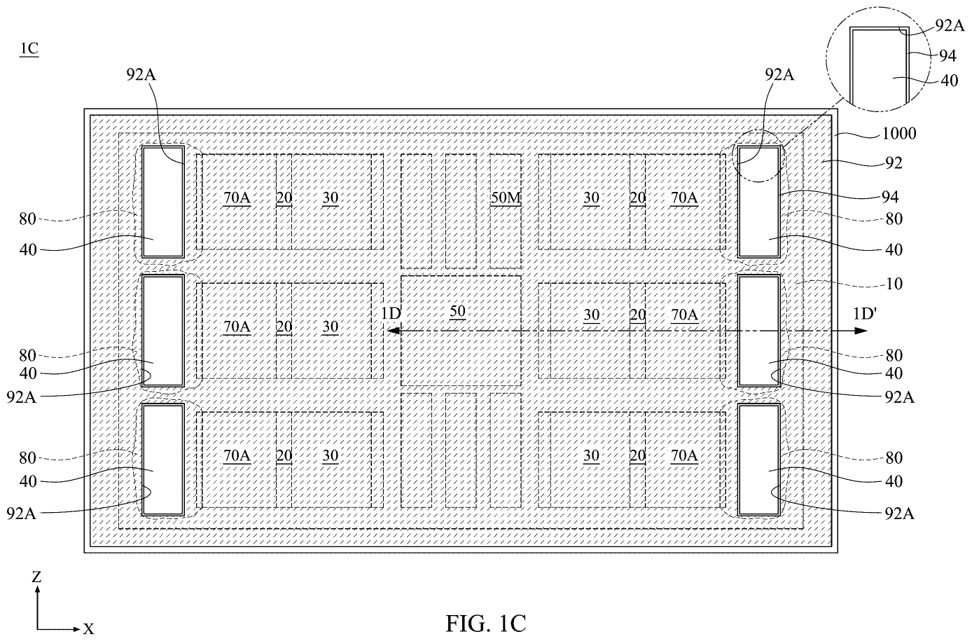

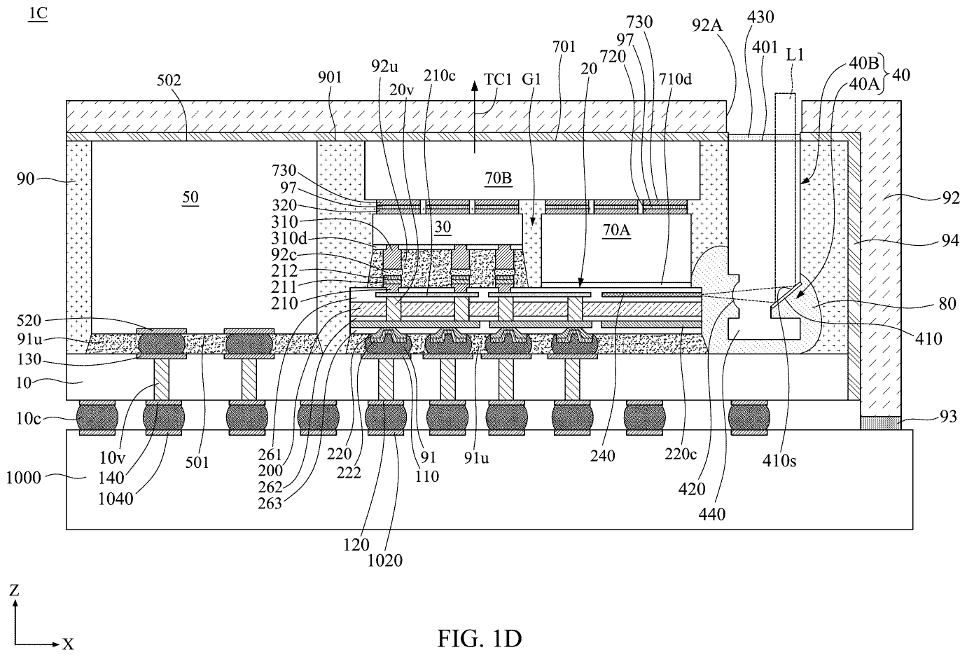

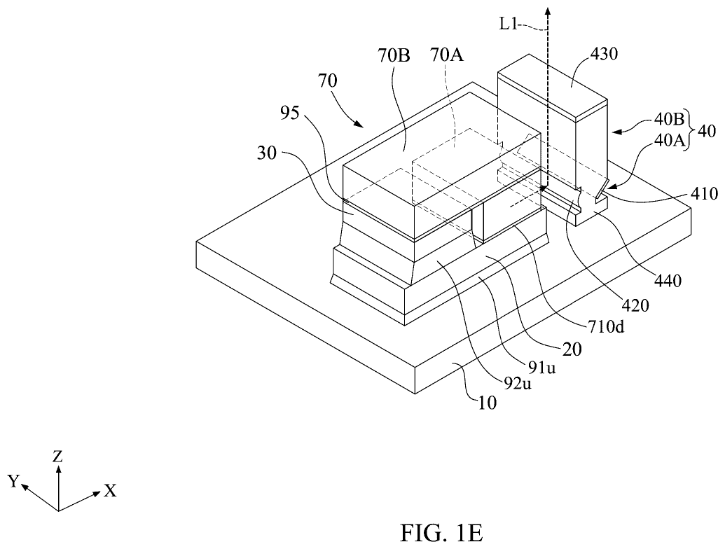

FIG. 1A is a top view of a package structure 1A in accordance with some arrangements of the present disclosure. FIG. 1B is a cross-section of a package structure 1A in accordance with some arrangements of the present disclosure. In some arrangements, FIG. 1B is a cross-section along a line 1B-1B′ in FIG. 1A. FIG. 1B may show a portion of the package structure 1A. Please be noted that some elements are omitted in FIG. 1A for clarity.

The package structure 1A may include substrates 10 and 1000, photonic components 20, electronic components 30, 50, and 50M, optical guiding components 40, reinforcement elements 70A and 70B, connection structures 80, an encapsulant 90, a thermal cooling component 92, and a thermal conductive adhesive 94. Each set of one photonic component 20 and one electronic component 30 may be referred to as an optical engine, and each of the optical engines may be optically coupled to one optical guiding component 40. The electronic component 50 may be arranged with a plurality of sets of optical engines and a plurality of corresponding electronic components 50M. The package structure 1A may be or include a chip-on-wafer-on-substrate (COWOS) structure.

The substrate 1000 may be or include a carrier, a printed circuit board (PCB), or a system board. The substrate 1000 may include conductive pads 1020 and 1040 exposed by a surface 1001. The substrate 1000 may support and electrically connect to the substrate 10.

The substrate 10 may support the photonic components 20, the optical guiding components 40, the electronic components 50 and 50M, and the connection structures 80. In some arrangements, the substrate 10 is electrically connected to the substrate 1000. The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and a plurality of conductive vias. In some embodiments, the substrate 10 includes a ceramic substrate, a metal plate, an organic substrate, a leadframe, or a semiconductor substrate (e.g., a substrate including GaN-based semiconductor materials). In some embodiments, the substrate 10 may include a two-layer substrate which includes a core layer and a conductive material and/or structure disposed on an upper surface and a bottom surface of the substrate 10. The conductive material and/or structure may include a plurality of conductive traces. In some arrangements, the substrate 10 includes conductive pads 110, 120, 130, and 140 and conductive vias 10v (also referred to as through silicon vias (TSVs)). The substrate 10 may be or include an interposer. The substrate 10 may be electrically connected to the substrate 1000 through the conductive pads 120, 140, 1020, and 1040 and electrical contacts 10c. The electrical contacts 10c may include solder balls or solder bars. In some arrangements, the electrical contacts 10c include controlled collapse chip connection (C4) bumps, a ball grid array (BGA), or a land grid array (LGA). Power signals may be supplied to the substrate 10 through the electrical contacts 10c, and the substrate 10 may be further connected to a voltage regulator, e.g., a low dropout (LDO) voltage regulator, for regulating the power signals.

The photonic components 20 may be disposed over and electrically connected to the substrate 10. The photonic component 20 may have an active surface facing the substrate 10 and a backside surface or a passive surface facing the electronic component 30. In some arrangements, the photonic component 20 is configured to optically couple to one or more optical components (e.g., optical fibers or a fiber array unit (FAU)). In some arrangements, the photonic component 20 is configured to optically couple to one or more optical components by edge coupling. The photonic component 20 may be or include a photonic integrated circuit (PIC), a laser diode, a receiver, a waveguide, a photodetector, a photodiode, a semiconductor optical amplifier (SOA), a grating coupler, a fiber coupling structure, an optical modulator (e.g., Mach-Zehnder modulator or microring modulator), or a combination thereof. The photonic component 20 may be referred to an optical domain controller that manages a unified collection of photoelectric conversion functions. In some arrangements, the package structure 1A is included in a wearable device or a haptic feedback module, e.g. a photon-driven micro haptic motor, and the photonic component 20 may be configured to control at least one auxiliary cutaneous actuator to achieve wearable skin simulation.

In some arrangements, the photonic component 20 includes a substrate layer 200, conductive pads 210 and 220, barrier layers 212 and 222, conductive layers 210c, 220c, and 211, conductive vias 20v, an optical channel 240, and dielectric layers 261, 262, and 263. The substrate layer 200 may be or include a semiconductor layer, e.g., a silicon layer. The conductive layers 211 may be formed on the conductive pads 210, the barrier layers 212 may be formed on the conductive layers 211, and the barrier layers 222 may be formed on the conductive pads 220. The conductive layer 210c may be or include a circuit layer. The circuit layer may include one or more circuits configured to provide a photoelectric conversion. The conductive vias 20v may electrically connect the conductive layer 210c to the conductive layer 220c. The conductive vias 20v may be referred to as through silicon vias (TSVs). The conductive layer 220c may be electrically connected to the conductive pads 220. The optical channel 240 may be configured to optically couple to one or more optical components (e.g., optical fibers or a fiber array unit (FAU)). The optical channel 240 may be or include an optical waveguide. The conductive pads 210 and 220, the conductive layers 210c, 220c, and 211, and the conductive vias 20v may include one or more conductive materials such as a metal or metal alloy. Examples include gold (Au), silver (Ag), aluminum (Al), copper (Cu), or an alloy thereof. The barrier layers 212 and 222 may include nickel (Ni). The photonic component 20 may have a thickness equal to or less than about 100 μm, 80 μm, 60 μm, or 50 μm, for example, about 50 μm to about 100 μm. In some arrangements, the portion including the conductive pads 210 and 220, the conductive layers 210c, 220c, and 211, and the conductive vias 20v may be referred to as an electrical transmission region, and the portion including the optical channel 240 may be referred to as an optical transmission region. The photonic component 20 may further include a calibration unit configured to compensate static and dynamic variations of optical signals within the optical channels 240. The static and dynamic variations of optical signals may be or include phase errors resulted from deviations caused by the optical channels (e.g. optical waveguides), interferometers, thermal shifts, process variations, and etc.

The electronic component 30 may be disposed or stacked over the photonic component 20. The electronic component 30 may have an active surface facing the photonic component 20 and a backside surface or a passive surface opposite to the active surface. In some arrangements, the electronic component 30 is electrically connected to the photonic component 20. In some arrangements, the electronic component 30 is electrically connected to the substrate 10 through the conductive vias 20v in the photonic component 20. In some arrangements, the electronic component 30 includes conductive pads 310 and at least a dielectric layer 310d. The conductive pad 310 may be referred to as a conductive pillar partially filled in an opening defined by the dielectric layer 310d. The conductive pads 310 may include Au, Ag, Al, Cu, Ni, or an alloy thereof. The dielectric layer 310d may include, for example, one or more organic materials (e.g., PA, PI, PBO, epoxy, and an epoxy-based material) or one or more inorganic materials (e.g., silicon oxide, silicon nitride, glass, and ceramic). In some arrangements, the dielectric layer 310d is or includes PI. In some arrangements, the electronic component 30 is electrically connected to the photonic component 20 through the conductive pads 310, connection elements 92c, the barrier layers 212, the conductive layers 211, and the conductive pads 210. The connection elements 92c may include conductive bumps. The connection elements 92c may be encapsulated by a protective element 92u. The protective element 92u may include an underfill. In some embodiments, the underfill includes an epoxy resin, a molding compound (e.g., an epoxy molding compound or other molding compound), polyimide, a phenolic compound or material, a material including a silicone dispersed therein, or a combination thereof. The electronic component 30 may be or include an electronic integrated circuit (EIC). In some arrangements, the electronic component 30 includes a logic circuit. In some arrangements, the electronic component 30 includes a modulator driver (DRV), a trans-impedance amplifier (TIA), or a combination thereof. The electronic component 30 may have a thickness equal to or greater than the thickness of the photonic component 20. The electronic component 30 may be referred to an electrical domain controller that manages a unified collection of pure electrical functions. Each set of one photonic component 20 and one electronic component 30 may be referred to as an optical engine, and the electronic component 50 may be arranged with a plurality of sets of optical engines. One or more of the optical engines may further include a crystal oscillator configured to provide stabilized clock signals so as to better control the modulator of the photonic component 20 and one or more clock signal contacts configured to receive the clock signals.

The optical guiding components 40 (also referred to as “optical guiding elements”) may be disposed over the substrate 10. In some arrangements, one or more of the optical guiding components 40 may be optically coupled to one or more of the photonic components 20. In some arrangements, each of the optical guiding components 40 is optically coupled to each of the photonic components 20. In some arrangements, the optical guiding component 40 is disposed external to the photonic component 20 and configured to change a transmission direction of an optical signal L1 from the photonic component 20. In some arrangements, the optical guiding component 40 is disposed at a lateral side of the photonic component 20 and configured to switch the transmission direction of the optical signal L1 between a substantially horizontal direction (e.g., x-axis) and a substantially vertical direction (e.g., z-axis). For example, in the process of transmitting the optical signal L1 from the photonic component 20 toward outside of the package structure 1A, the optical guiding component 40 is configured to switch the transmission direction of the optical signal L1 in a substantially horizontal direction (e.g., x-axis) toward a substantially vertical direction so as to emit out of the package structure 1A.

In some arrangements, the optical guiding component 40 includes a switch portion 40A and a transmission portion 40B. In some arrangements, the switch portion 40A and the transmission portion 40B are connected to each other. The switch portion 40A and the transmission portion 40B may be formed integrally as a monolithic piece. Alternatively, the switch portion 40A and the transmission portion 40B may be formed separately and then assembled to each other.

In some arrangements, the optical guiding component 40 (or the switch portion 40A) includes a reflective surface 410s configured to reflect the optical signal L1 to change the transmission direction of the optical signal L1. In some arrangements, the optical guiding component 40 (or the switch portion 40A) includes a reflective layer 410 (also referred to as “a reflective element”) defining the reflective surface 410s. The reflective layer 410 includes a metal layer. In some arrangements, the reflective element (e.g., the reflective layer 410) is configured to change the transmission direction of the optical signal L1 from the optical channel 240. In some arrangements, the optical guiding component 40 (or the switch portion 40A) further includes a lens 420 facing the optical channel 240 of the photonic component 20. In some arrangements, the reflective element (e.g., the reflective layer 410) is configured to reflect the optical signal L1 transmitted through the lens 420. In some arrangements, the transmission portion 40B is configured to transmit the optical signal L1 from the switch portion 40A upwardly. In some arrangements, the transmission portion 40B includes an antireflective element 430 on a surface 401 of the optical guiding component 40. The surface 401 may be referred to as an emitting surface.

In some arrangements, the optical guiding component 40 (or the switch portion 40A) further includes a base 440. The base 440 may define a protrusion that is protruded with respect to the lens 420. The reflective surface 410s and a portion of the base 440 are spaced apart from each other by a gap. The protruded base 440 may define recesses in which portions of the connection structure 80 are filled so as to form an interlock mechanism which can increase the adhesion between the optical guiding component 40 and the connection structure 80.

In some arrangements, the switch portion 40A includes a first transparent body which defines the lens 420 and a portion of the optical path for the optical signal L1, and the reflective layer 410 including metal is formed on a surface of the first transparent body. In some arrangements, the transmission portion 40B includes a second transparent body which defines another portion of the optical path for the optical signal L1, and the antireflective element 430 is formed on a surface (e.g., the surface 401) of the second transparent body. The transparent bodies may be formed of or include silicon, sol-gel glass, transparent polymer, or any suitable optically transparent materials. In some arrangements, the optical guiding component 40 (or the optical guiding element) is configured to redirect, concentrate, or diffuse the optical signal L1 based on a predetermined distribution profile of the optical guiding component 40. According to some arrangements of the present disclosure, with the above design, the optical signal L1 can be used in an optoelectronic inspection during a manufacturing process of the package structure, particularly before a singulation operation is performed, and thus the yield can be increased.

The electronic component 50 may be disposed over and electrically connected to the substrate 10. The electronic component 50 may have a surface 501 facing the substrate 10 and a surface 502 opposite to the surface 501. The surface 501 may be an active surface. The surface 502 may be a backside surface or a passive surface. In some arrangements, the electronic component 50 includes conductive pads 520 exposed by the surface 501. In some arrangements, the electronic component 50 is electrically connected to the photonic component 20 through the substrate 10. In some arrangements, the electronic component 50 may be or include a processing component, e.g., an ASIC, an FPGA, a GPU, or the like, or a combination thereof. Each set of one photonic component 20 and one electronic component 30 may be referred to as an optical engine, and the electronic component 50 may be arranged with a plurality of sets of optical engines to transmit electrical signals through optical transmission.

The electronic components 50M may be disposed over and electrically connected to the substrate 10. In some arrangements, the electronic components 50M are disposed around or adjacent to the electronic component 50. In some arrangements, the electronic components 50M are electrically connected to the electronic component 50 through the substrate 10. In some arrangements, the electronic component 50M may be or include a storage component, e.g., a memory device, for example, a high bandwidth memory (HBM) component, or the like, or a combination thereof. The electronic component 50 (the processing component) may be arranged with a plurality of electronic components 50M (the storage components). There may be various permutations of the electronic components 50 and 50M, for example, the electronic components 50M may be disposed at three or four lateral sides of the electronic component 50 instead of two opposite lateral sides. The sets of photonic components 20 and electronic components 30 may be arranged according to the respective permutations of the electronic components 50 and 50M according to actual applications.

The reinforcement element 70A may be disposed over and connected to the photonic component 20. In some arrangements, the reinforcement element 70A is connected to the photonic component 20 through an electrically isolated connection element. The electrically isolated connection element may include a dummy connection element. In some arrangements, the reinforcement element 70A includes a dielectric layer 710d. In some arrangements, the dielectric layer 710d is connected to the dielectric layer 210d through a thermal bonding process. The dielectric layer 710d may include, for example, one or more organic materials (e.g., PA, PI, PBO, epoxy, and an epoxy-based material) or one or more inorganic materials (e.g., silicon oxide, silicon nitride, glass, and ceramic). In some arrangements, the dielectric layer 710d is or includes PI. In some arrangements, the reinforcement element 70A includes a discrete component that is distinct from the photonic component 20. In some arrangements, the reinforcement element 70A is free of a logic circuit. In some arrangements, the reinforcement element 70A includes a dummy substrate (e.g., a dummy silicon substrate), a dummy die, or the like. In some arrangements, the reinforcement element 70A includes a dummy die free of a logic circuit. The reinforcement element 70A may have a thickness equal to or greater than the thickness of the photonic component 20. The reinforcement element 70A may have a thickness substantially the same as the thickness of the electronic component 30.

In some arrangements, the reinforcement element 70B is disposed over the electronic component 30 and the reinforcement element 70A. In some arrangements, the reinforcement element 70B is supported by the electronic component 30 and the reinforcement element 70A. In some arrangements, the reinforcement element 70B vertically overlaps a gap G1 between the electronic component 30 and the reinforcement element 70A. In some arrangements, the reinforcement element 70B is connected to the electronic component 30 and the reinforcement element 70A through an adhesive layer 95. The adhesive layer 95 may be or include an insulating adhesive. The adhesive layer 95 may be or include a die attach films (DAF). The adhesive layer 95 may include a thermal interface material (TIM). In some arrangements, the reinforcement element 70B is configured to provide a thermal channel TC1 substantially perpendicular to the optical channel 240 of the photonic component 20 so as to increase heat transfer to outside of the package structure 1A. According to some arrangements of the present disclosure, the adhesive layer 95 (e.g., the TIM) is used to connect the reinforcement element 70B to the reinforcement element 70A and the electronic component 30, the processing steps can be simplified, the cost can be reduced, and the heat dissipation effect can be improved.

In some arrangements, the reinforcement element 70B includes a discrete component that is distinct from the photonic component 20, the electronic component 30, and the reinforcement element 70A. In some arrangements, the reinforcement element 70B is free of a logic circuit. In some arrangements, the reinforcement element 70B includes a dummy substrate (e.g., a dummy silicon substrate), a dummy die, or the like. In some arrangements, the reinforcement element 70B includes a dummy die free of a logic circuit. The reinforcement element 70B may have a thickness equal to or greater than the thickness of the photonic component 20. The reinforcement element 70B may have a thickness be substantially the same as or greater than the thickness of the reinforcement element 70A. In some arrangements, the reinforcement elements 70A and 70B collectively form a reinforcement structure. The photonic component 20, the electronic component 30, and the reinforcement elements 70A and 70B may be collectively referred to as a sub-package.

The connection structures 80 may be disposed over the substrate 10. In some arrangements, one or more of the connection structures 80 may connect one or more of the optical guiding components 40 to one or more of the photonic components 20. In some arrangements, each of the connection structures 80 connects each of the optical guiding components 40 to each of the photonic components 20. In some arrangements, the connection structure 80 is configured to reduce scattering of the optical signal L1 during transmission. In some arrangements, the connection structure 80 includes a portion between the optical channel 240 and the lens 420. In some arrangements, a reflective element (e.g., the reflective layer 410) configured to change the transmission direction of the optical signal L1 from the optical channel 240 is disposed external to the photonic component 20 and spaced apart from the optical channel 240 of the photonic component 20 by an optical fastener (e.g., the connection structure 80) and the lens 420, and the optical fastener (e.g., the connection structure 80) and the lens 420 (or the transparent body of the switch portion 40A) have different refractive indexes. In some arrangements, the refractive index of the connection structure 80 is lower than the refractive index of the lens 420 (or the transparent body of the switch portion 40A). The refractive index of the connection structure 80 is lower than about 1.5, e.g., about 1.3, 1.2, or 1, and the refractive index of the lens 420 (or the transparent body of the switch portion 40A) is greater than about 1.5. e.g., about 1.8, 2, 2.5, or 3.

In some arrangements, the connection structure 80 (or the optical fastener) contacts the substrate 10, the optical channel 240, the reflective layer 410, and the lens 420. In some arrangements, the connection structure 80 contacts the substrate 10, the optical channel 240 of the photonic component 20, and the optical guiding component 40. In some arrangements, the connection structure 80 includes an optical gel. In some arrangements, the connection structure 80 has an irregular profile from a cross-sectional view perspective. In some arrangements, the connection structures 80 may be referred to as optical islands that connect the optical guiding components 40 to the photonic components 20 and allow the optical signals L1 to transmit therethrough. The optical guiding components 40 may be partially embedded in the optical islands. In some arrangements, the switch portion 40A is embedded in the connection structure 80. The photonic component 20, the electronic component 30, the optical guiding component 40, the reinforcement elements 70A and 70B, and the connection structure 80 may be collectively referred to as a sub-package. In some arrangements, the connection structure 80 and the lens 420 are collectively referred to as an integrated alignment structure, and the reflective layer 410 (or the reflective element) is fixedly coupled to the photonic component 20 via the integrated alignment structure.

The encapsulant 90 may be disposed over the substrate 10. In some arrangements, the encapsulant 90 encapsulates the photonic components 20, the optical guiding components 40, the electronic components 30, 50, and 50M, the reinforcement elements 70A and 70B, and the connection structures 80. In some arrangements, the encapsulant 90 encapsulates the reflective elements (e.g., the reflective layers 410). In some arrangements, the surface 401 of the optical guiding component 40 is exposed by the encapsulant 90. The encapsulant 90 may include an epoxy resin, a molding compound (e.g., an epoxy molding compound or other molding compound), polyimide, a phenolic compound or material, a material including a silicone dispersed therein, or a combination thereof. In some arrangements, the connection structure 80, the protective element 91u, and the encapsulant 90 may be collectively referred to as a fastener assembly to fasten the optical guiding component 40 to the photonic component 20.

The thermal cooling component 92 may be disposed and connected to the substrate 1000. In some arrangements, the thermal cooling component 92 covers the encapsulant 90 and the reinforcement structure (e.g., the reinforcement elements 70A and 70B). In some arrangements, the thermal cooling component 92 covers the encapsulant 90 and the reinforcement structure (e.g., the reinforcement elements 70A and 70B). In some arrangements, a heat dissipation rate of the encapsulant 90 is lower than a heat dissipation rate of the reinforcement element 70B. In some arrangements, a heat dissipation rate of the encapsulant 90 is lower than a heat dissipation rate of the thermal cooling component 92. In some arrangements, in additional to the thermal channel TC1 provided by the reinforcement element 70B, the thermal cooling component 92 is configured to provide additional thermal cooling effects. In some arrangements, a portion of the optical guiding component 40 is exposed by an opening 92A of the thermal cooling component 92. In some arrangements, the thermal cooling component 92 is connected to the substrate 1000 through a connection element 93. The thermal cooling component 92 may be or include a metal plate. The connection element 93 may include a solder bump, an adhesive layer, or the like.

The thermal conductive adhesive 94 may be between the encapsulant 90 and the thermal cooling component 92. In some arrangements, the thermal cooling component 92 is adhered to the encapsulant 90 and lateral edges of the substrate 10 by the thermal conductive adhesive 94. The thermal conductive adhesive 94 may include a thermal interface material (TIM).

Referring to FIG. 1A, in some arrangements, the thermal cooling component 92 includes a plurality of openings 92A. In some arrangements, three optical guiding components 40 are exposed by one opening 92A from a top view perspective. In some arrangements, one or more of the connection structures 80 have irregular profiles from a top view perspective. In some arrangements, one or more of the connection structures 80 have different irregular profiles from a top view perspective. In some arrangements, portions of the substrate 10 and portions of the connection structures 80 are exposed by the openings 92A from a top view perspective. In some arrangements, referring to FIGS. 1A and 1B, the electronic components 50 and 50M and the reinforcement element 70B are covered by the thermal cooling component 92 with surfaces 502 and 701 contacting the thermal conductive adhesive 94, such that heat dissipation can be improved.

FIG. 1C is a top view of a package structure 1C in accordance with some arrangements of the present disclosure. FIG. 1D is a cross-section of a package structure 1C in accordance with some arrangements of the present disclosure. In some arrangements, FIG. 1D is a cross-section along a line 1D-1D′ in FIG. 1C. FIG. 1D may show a portion of the package structure 1C. Please be noted that some elements are omitted in FIG. 1C for clarity. The package structure 1C is similar to the package structure 1A, and the differences therebetween are described as follows.

In some arrangements, the reinforcement element 70B is connected to the electronic component 30 through a solder-free conductive structure. The solder-free conductive structure between the reinforcement element 70B and the electronic component 30 may include the conductive pad 320, a connection element 97, and a pad 730 of the reinforcement element 70B. In some arrangements, the reinforcement element 70B is connected to the reinforcement element 70A through a solder-free conductive structure. The solder-free conductive structure between the reinforcement element 70B and the reinforcement element 70A may include the pad 720, a connection element 97, and a pad 730 of the reinforcement element 70B. In some arrangements, the connection element 97 is free of a solder material. In some arrangements, the connection element 97 includes an alloy or an intermetallic compound (IMC) layer. In some arrangements, the connection element 97 between the reinforcement element 70B and the electronic component 30 includes an IMC layer formed of metals from the pad 730 and the conductive pad 320. In some arrangements, the connection element 97 between the reinforcement element 70B and the reinforcement element 70A includes an IMC layer formed of metals from the pad 730 and the pad 720.

Referring to FIG. 1C, in some arrangements, one optical guiding component 40 is exposed by one opening 92A from a top view perspective. In some arrangements, referring to FIGS. 1C and 1D, a portion of the thermal conductive adhesive 94 is exposed by the opening 92A from a top view perspective. In some arrangements, the opening 92A is wider or larger than the surface 401 of the optical guiding component 40 so as to provide an alignment tolerance between the thermal cooling component 92 and the optical guiding component 40.

FIG. 1E is a perspective view of a portion of a package structure in accordance with some arrangements of the present disclosure. In some arrangements, FIG. 1E shows a perspective view of a portion of the package structure 1A and/or a portion of the package structure 1C.

In some arrangements, the reflective layer 410 and the lens 420 extend in substantially parallel directions (e.g., y-axis). In some arrangements, despite that only one optical signal L1 is shown in FIG. 1E, a plurality of optical signals from a plurality of optical channels of the photonic component 20 may be transmitted through the lens 420 and reflected by the reflective layer 410.

According to some arrangements of the present disclosure, the optical guiding components 40 allow optical signal L1 from the optical channel 240 to switch its transmission direction from a substantially horizontal direction to a substantially vertical direction, and thus an optoelectronic inspection from above the photonic component 20 through vertical coupling can be performed before a singulation operation. Therefore, only the singulated units (e.g., the structure including the photonic components 20 with the electronic components 30 disposed thereon) pass the inspection may be further connected to the substrate 1000 to form the package structure, and the singulated units (e.g., the structure including the photonic components 20 with the electronic components 30 disposed thereon) fail the inspection may be discarded or reworked. As such, only the singulated unit considered as a “know-good-die” may be used to form the package structure. Therefore, the manufacturing process of the package structure can be simplified without having to be reworked if the photonic component 20 of the singulated unit is determined to fail the inspection after singulation, and the cost can be reduced.

In addition, according to some arrangements of the present disclosure, the optical guiding component 40 includes a reflective surface 410s that is configured to switch the transmission direction of the optical signal L1 by reflection. Therefore, a vertical transmission can be achieved by edge coupling of the optical signal L1 without arranging a grating coupler by grating coupling, and the band width of the optical signal L1 can be increased compared to the optical signal coupled by a grating coupler, thus the optical coupling efficiency can be increased.

Moreover, according to some arrangements of the present disclosure, the photonic component 20 and the optical guiding component 40 are optically coupled to each other through the connection structure 80 with the photonic component 20 and the optical guiding component 40 are both partially embedded therein. Due to the above design, despite that the encapsulant 90 encapsulates the photonic component 20, the optical guiding component 40, and the connection structure 80, the optical signal L1 can be transmitted from the photonic component 20 to the optical guiding component 40 and emitted out of the package structure through the optical guiding component 40. Therefore, the wafer-level optoelectronic inspection can be performed even with the wafer-level structure has been encapsulated by the encapsulant 90.

Furthermore, according to some arrangements of the present disclosure, the reinforcement elements 70A and 70B collectively are configured to construct a continuous structure in a direction (e.g., x-axis) substantially parallel to the active surface of the photonic component 20, the structural strength of the entire photonic component 20 can be increased significantly. Therefore, the warpage can be reduced, the optical alignment can be improved, and the reliability of the package structure can be increased.

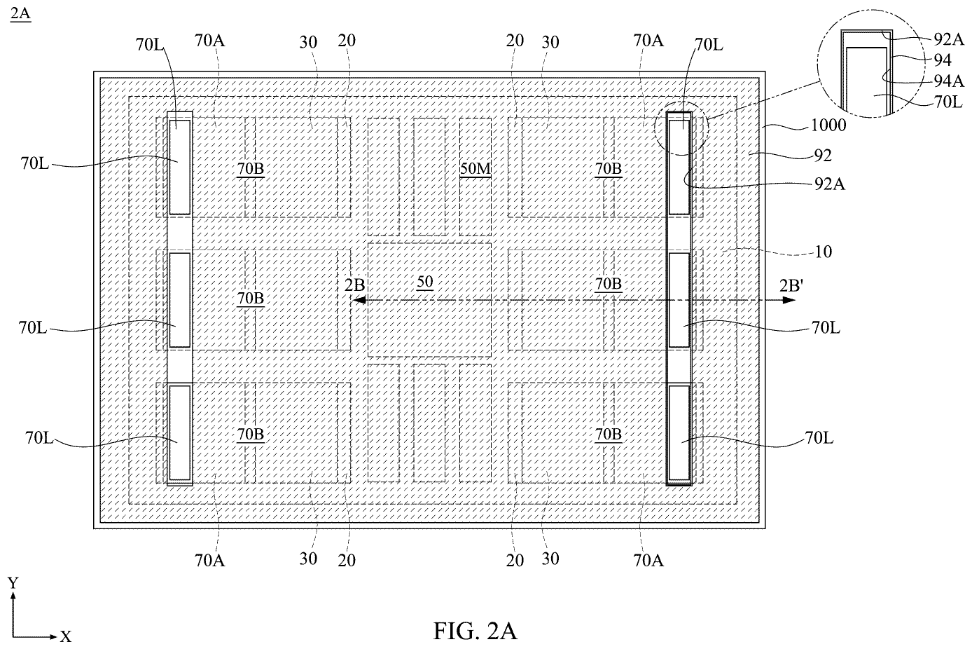

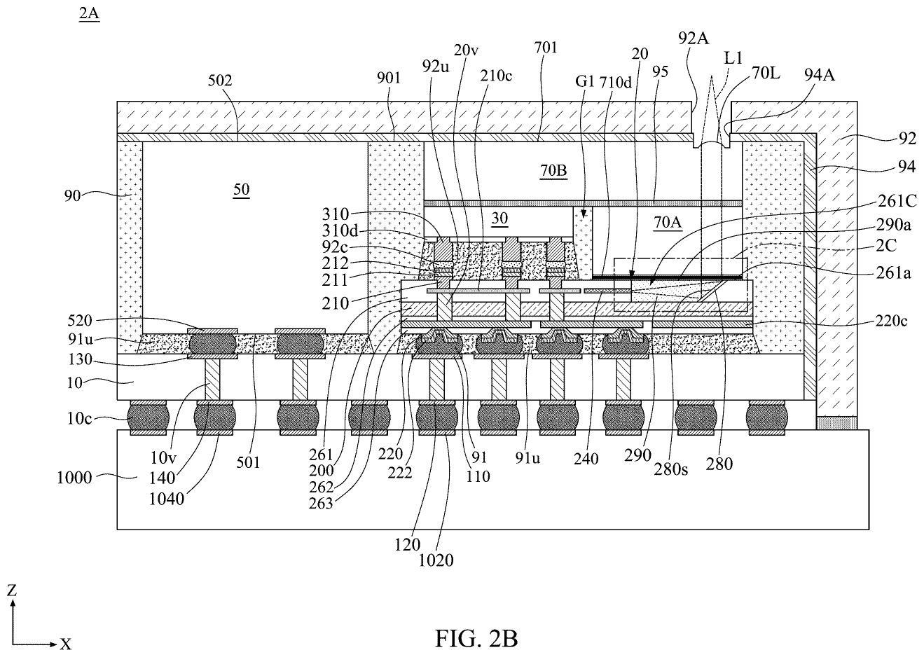

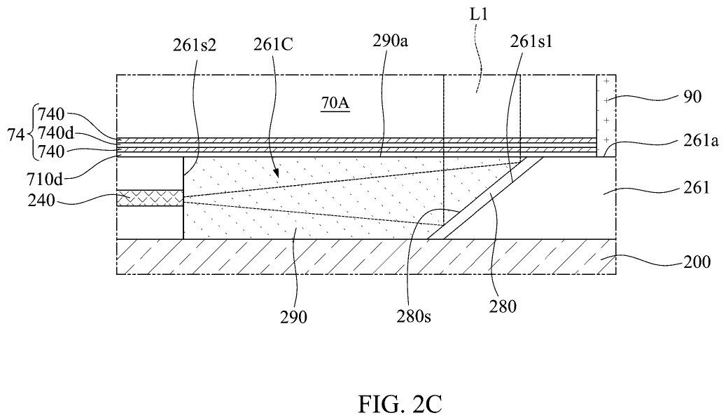

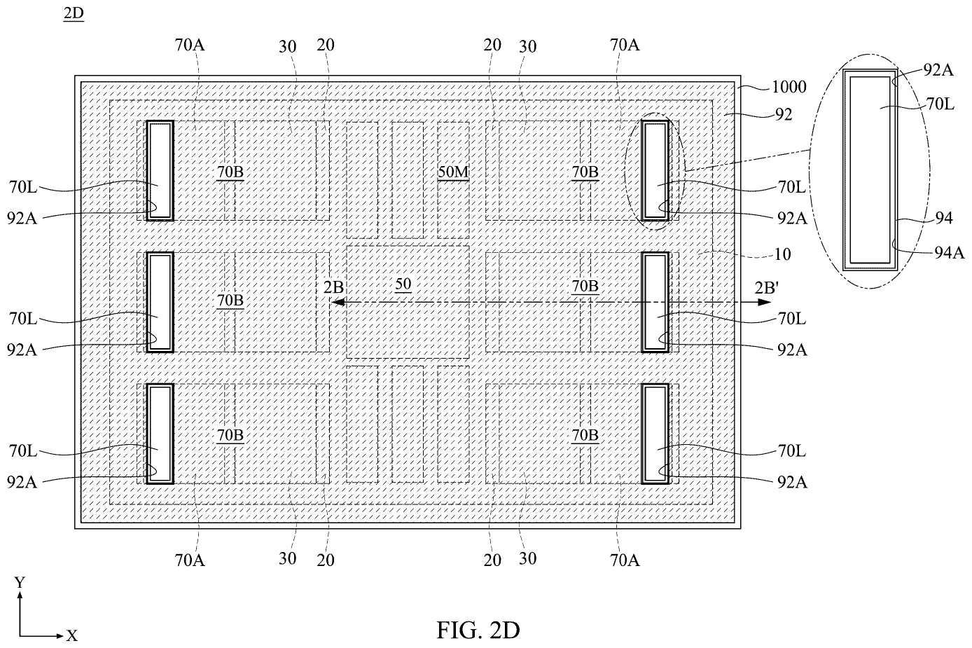

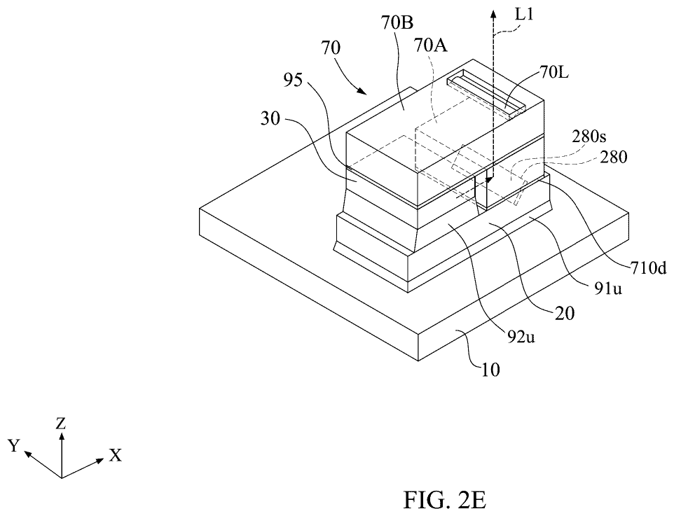

FIG. 2A is a top view of a package structure 2A in accordance with some arrangements of the present disclosure. FIG. 2B is a cross-section of a package structure 2A in accordance with some arrangements of the present disclosure. In some arrangements, FIG. 2B is a cross-section along a line 2B-2B′ in FIG. 2A. FIG. 2B may show a portion of the package structure 2A. Please be noted that some elements are omitted in FIG. 2A for clarity. The package structure 2A is similar to the package structure 1A, and the differences therebetween are described as follows.

The package structure 2A may include substrates 10 and 1000, photonic components 20, electronic components 30, 50, and 50M, optical guiding components (or optical guiding elements), reinforcement elements 70A and 70B, an encapsulant 90, a thermal cooling component 92, and a thermal conductive adhesive 94.

In some arrangements, the optical guiding component includes an optical coupling portion 290 and a reflective element 280. The reflective element 280 may define a reflective surface 280s. In some arrangements, the optical guiding component is corresponding to one of the photonic component 20. In some arrangements, each of the optical guiding components is corresponding to each of the photonic components 20. In some arrangements, the optical guiding component is configured to direct the optical signal L1 from the optical channel 240 to transmit along an optical path embedded in the encapsulant 90 and emit out of the encapsulant 90. In some arrangements, the optical channel 240 is covered by the dielectric layer 261, and a portion of the optical channel 240 is exposed by the dielectric layer 261 and contacts the optical guiding component (e.g., the optical coupling portion 290). In some arrangements, the optical guiding element is configured to redirect, concentrate, or diffuse the optical signal L1 based on a predetermined distribution profile of the optical guiding element. According to some arrangements of the present disclosure, with the above design, the optical signal L1 can be used in an optoelectronic inspection during a manufacturing process of the package structure, particularly before a singulation operation is performed, and thus the yield can be increased.

In some arrangements, the optical coupling portion 290 and the reflective element 280 are embedded in the photonic component 20. In some arrangements, the optical coupling portion 290 and the reflective element 280 are in a recess 261C defined by the dielectric layer 261. In some arrangements, a top surface 290a of the optical coupling portion 290 is substantially aligned with a top surface 261a of the dielectric layer 261. In some arrangements, the reflective element 280 is configured to change the transmission direction of the optical signal L1 from the optical channel 240. In some arrangements, the encapsulant 90 encapsulates the reflective elements 280. In some arrangements, a reflective surface 280s defined by the reflective element 280 is inclined with respect to the top surface 261a of the dielectric layer 261. In some arrangements, the reinforcement structure (e.g., the reinforcement elements 70A and 70B) defines the optical path for the optical signal L1. In some arrangements, the reinforcement element 70A (or the dummy die) is over the reflective element 280 and configured to transmit the optical signal L1 reflected by the reflective element 280 toward outside of the package structure 2A.

In some arrangements, the reinforcement structure (or the reinforcement element 70B) includes a lens 70L configured to emit the optical signal L1 out of the encapsulant 90. In some arrangements, the lens 70L is exposed by the opening 92A of the thermal cooling component 92. In some arrangements, the lens 70L is exposed by an opening 94A of the thermal conductive adhesive 94. In some arrangements, the thermal conductive adhesive 94 is partially exposed by the opening 92A of the thermal cooling component 92 from a top view perspective. The lens 70L may merge the intensity of the optical signal L1 that have been scattered after passing through the reinforcement elements 70A and 70B. Therefore, the intensity of the optical signal L1 can be concentrated and calibrated.

In some arrangements, the reflective element 280 includes a metal layer. In some arrangements, the optical coupling portion 290 includes an optical gel, a dielectric layer, or the like.

FIG. 2C is a cross-section of a portion 2C of a package structure 2A in accordance with some arrangements of the present disclosure.

In some arrangements, the package structure 2A further includes an optical laminate 74 between the reinforcement element 70A (or the dummy die) and the reflective element 280. In some arrangements, the optical laminate 74 connects the reinforcement element 70A (or the dummy die) to the photonic component 20.

In some arrangements, the optical laminate 74 includes antireflective layers 740 and dielectric layers 710 and 740d. In some arrangements, the antireflective layer 740 is between the reinforcement element 70A (or the dummy die) and the photonic component 20. In some arrangements, the dielectric layer 710d is thermally bonded to the dielectric layer 261 of the photonic component 20. In some arrangements, the optical coupling portion 290 and the optical laminate 74 are collectively referred to as an integrated alignment structure, and the reflective element 280 is fixedly coupled to the optical channel 240 of the photonic component 20 via the integrated alignment structure.

In some arrangements, the recess 261C of the dielectric layer 261 is defined by lateral surfaces 261s1 and 261s2. In some arrangements, the reflective element 280 is disposed or formed on the lateral surface 261s1 that is inclined with respect to the top surface 261a, and the optical channel 240 is exposed by the lateral surface 261s2. In some arrangements, the reflective surface 280s is substantially parallel to the lateral surface 261s1.

FIG. 2D is a top view of a package structure 2D in accordance with some arrangements of the present disclosure. In some arrangements, FIG. 2B is a cross-section along a line 2B-2B′ in FIG. 2D. Please be noted that some elements are omitted in FIG. 2D for clarity.

Referring to FIG. 2D, in some arrangements, one optical guiding component 40 is exposed by one opening 92A from a top view perspective. In some arrangements, a portion of the thermal conductive adhesive 94 is exposed by the opening 92A from a top view perspective.

FIG. 2E is a perspective view of a portion of a package structure in accordance with some arrangements of the present disclosure. In some arrangements, FIG. 2E shows a perspective view of a portion of the package structure 2A.

In some arrangements, the reflective element 280 and the lens 70L extend in substantially parallel directions (e.g., y-axis). In some arrangements, despite that only one optical signal L1 is shown in FIG. 2E, a plurality of optical signals from a plurality of optical channels of the photonic component 20 may be reflected by the reflective element 280 and transmitted through the lens 70L.

According to some arrangements of the present disclosure, the reinforcement elements 70A and 70B allow the optical signal L1 to pass through, and the reinforcement elements 70A and 70B collectively are configured to construct a continuous structure in a direction (e.g., x-axis) substantially parallel to the active surface of the photonic component 20, and thus the structural strength of the entire photonic component 20 can be increased significantly. Therefore, reinforcement elements 70A and 70B can achieve both transmitting optical signals L1 and reducing the warpage, thus wafer-level optoelectronic inspection can be achieved, the optical alignment can be improved, and the reliability of the package structure can be increased.

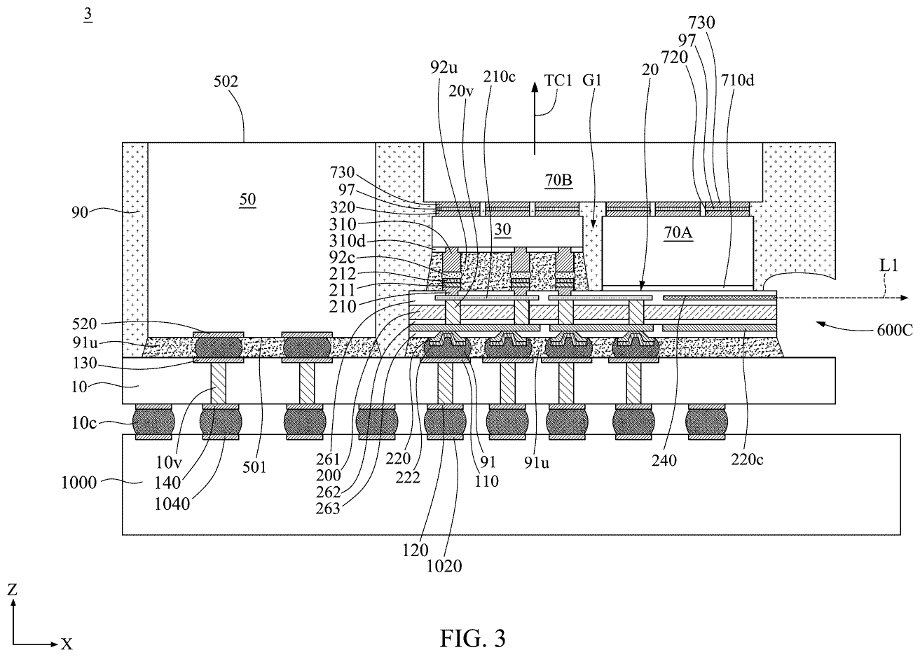

FIG. 3 is a cross-section of a package structure 3 in accordance with some arrangements of the present disclosure. The package structure 3 is similar to the package structure 1C, and the differences therebetween are described as follows.

In some arrangements, the encapsulant 90 defines a recess 600C that exposes the optical channel 240 of the photonic component 20. In some arrangements, the optical signal L1 transmitted from the optical channel 240 can be emitted out of the package structure 3 without being blocked by the encapsulant 90.

According to some arrangements of the present disclosure, optical signals L1 can be transmitted horizontally through the optical channel 240 exposed by the recess 600C of the encapsulant 90. When power is supplied from the substrate 1000 below and heat is dissipation through the thermal channel TC1 upwards, there is hardly space for vertically transmission of optical signals. With the above design, optical transmission can be achieved with a relatively simple structure without having to arrange multiple optical transmission components to the package structure.

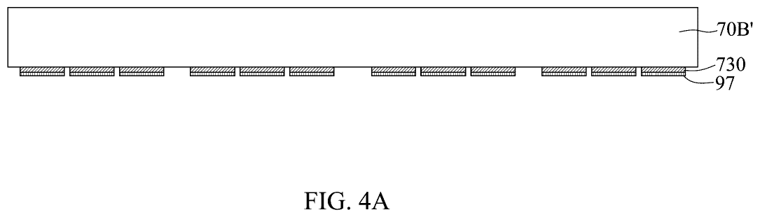

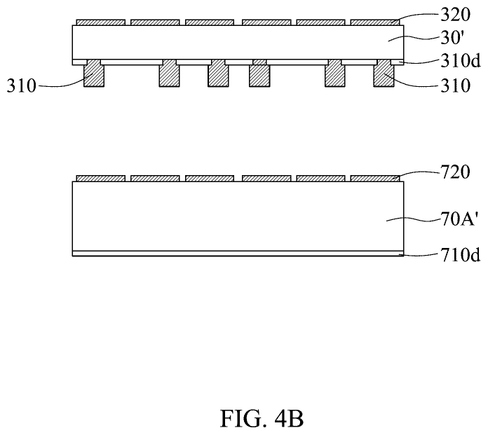

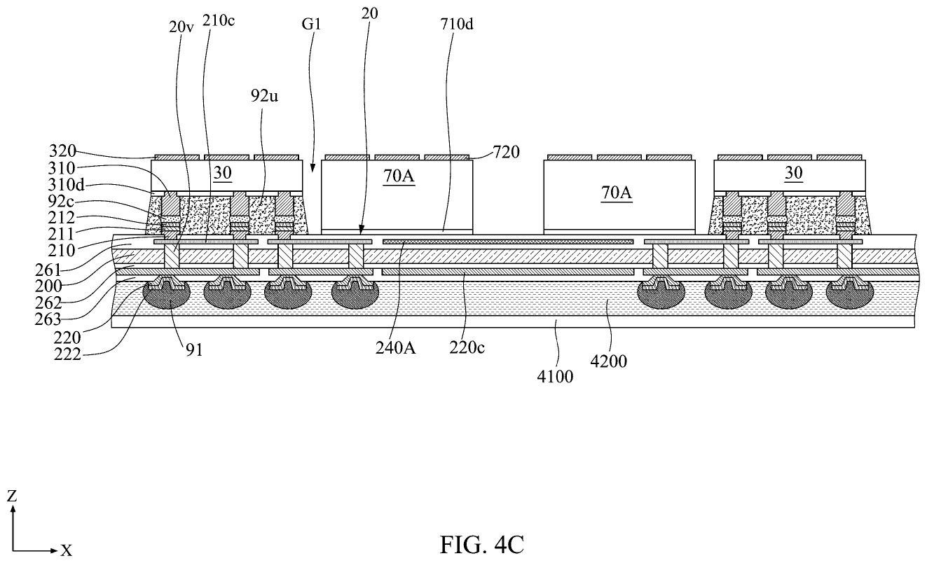

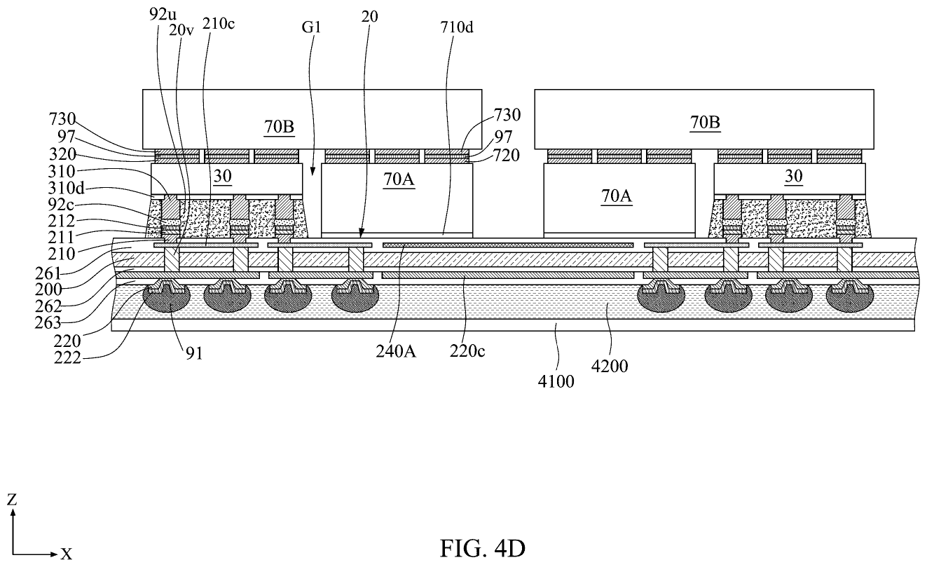

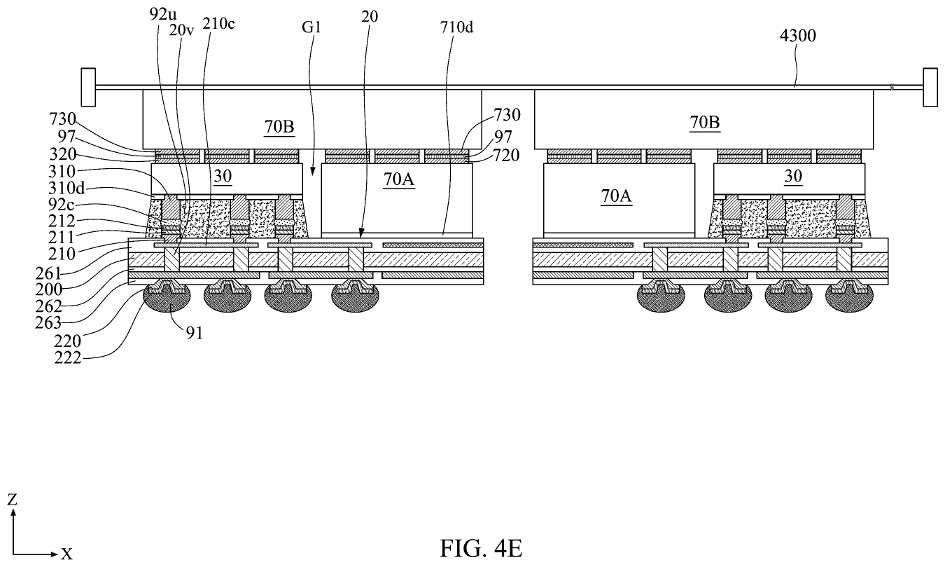

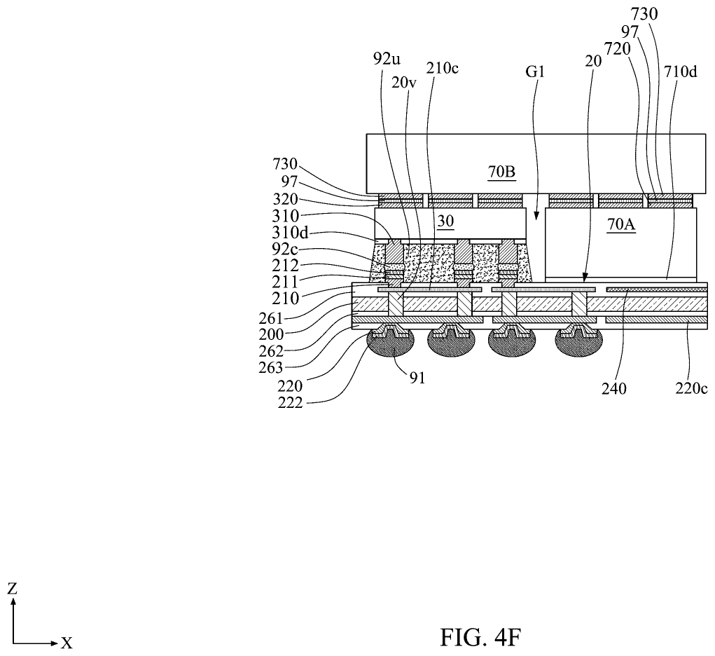

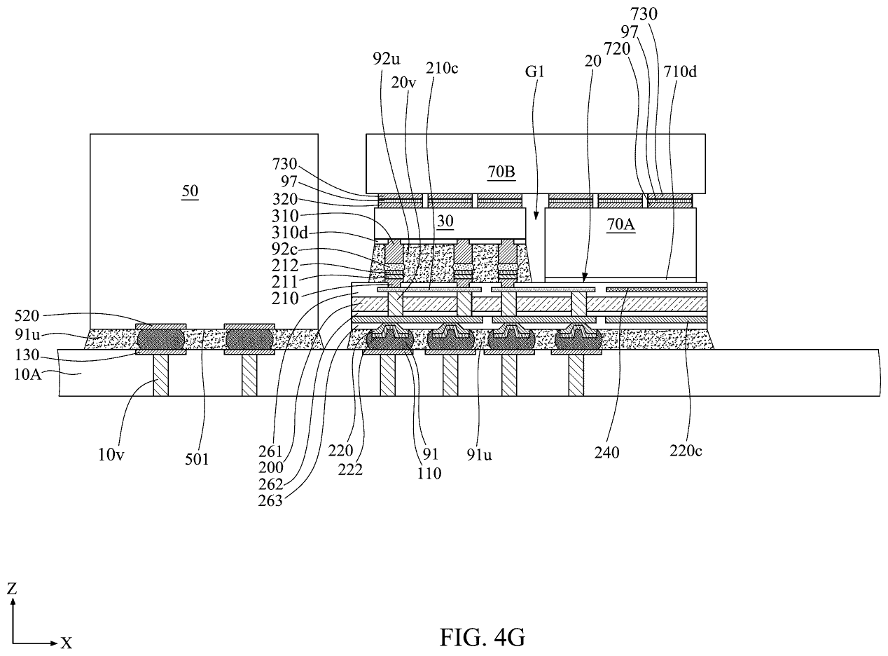

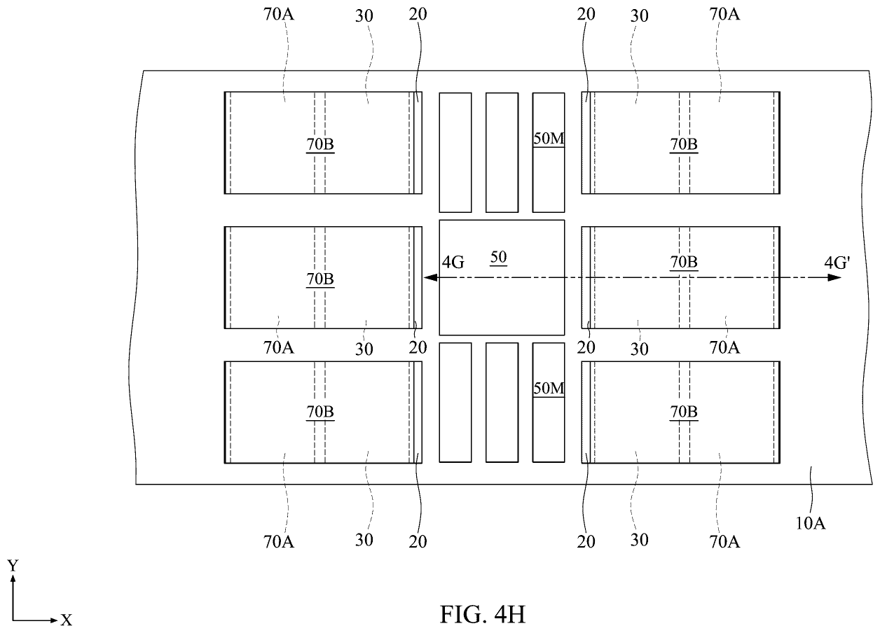

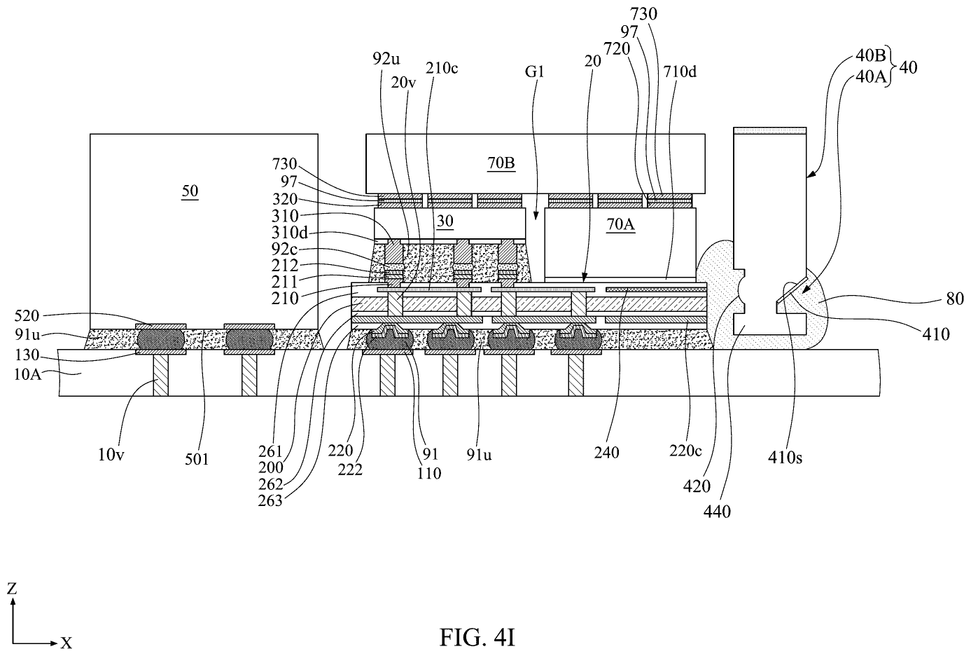

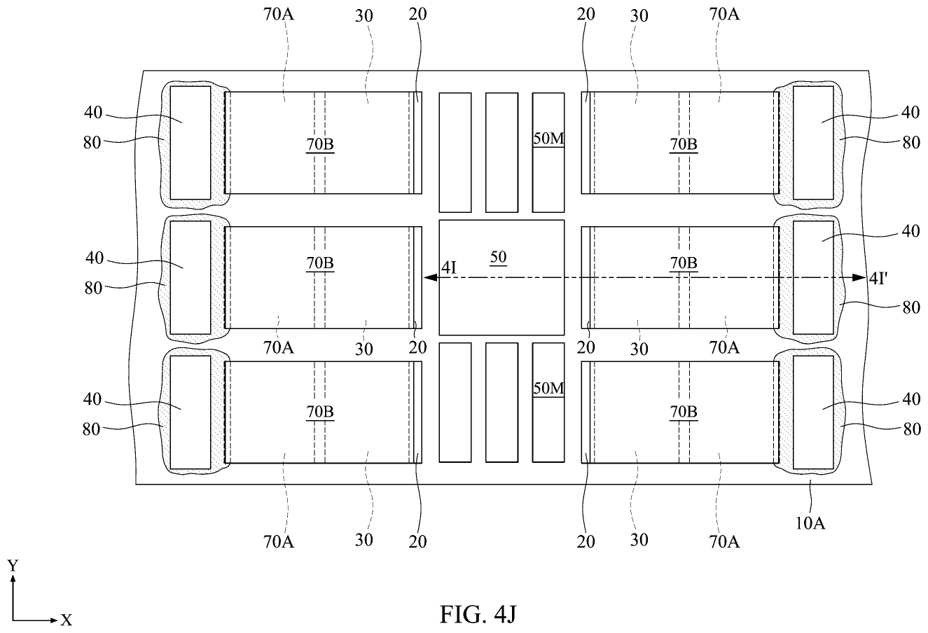

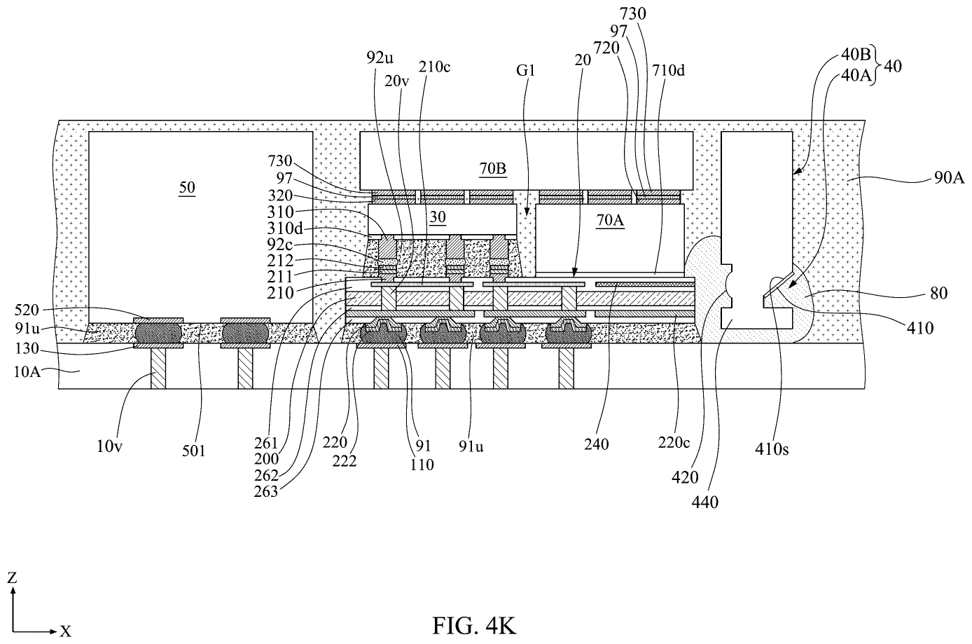

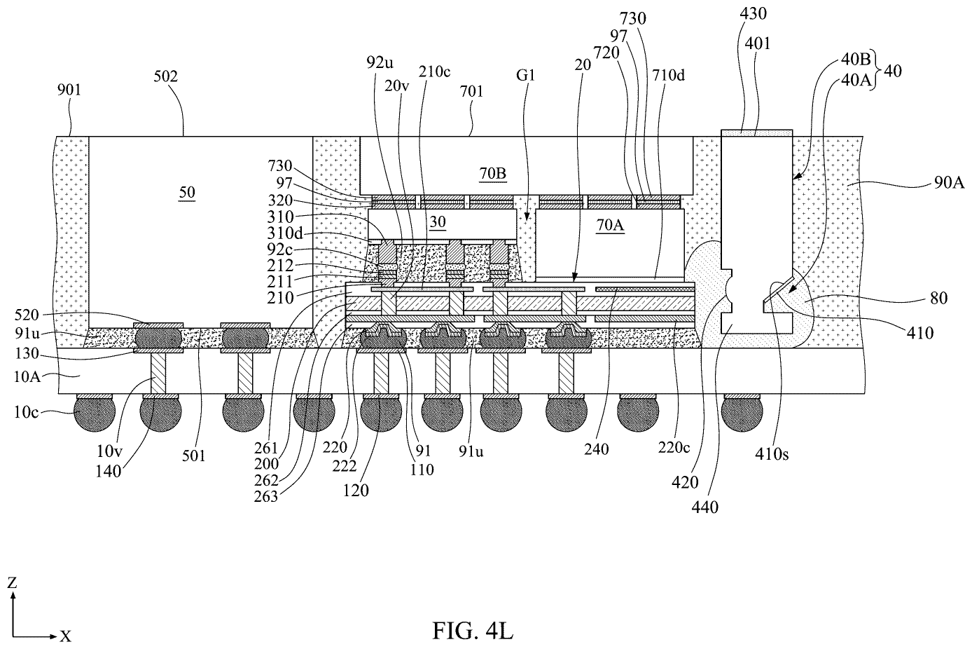

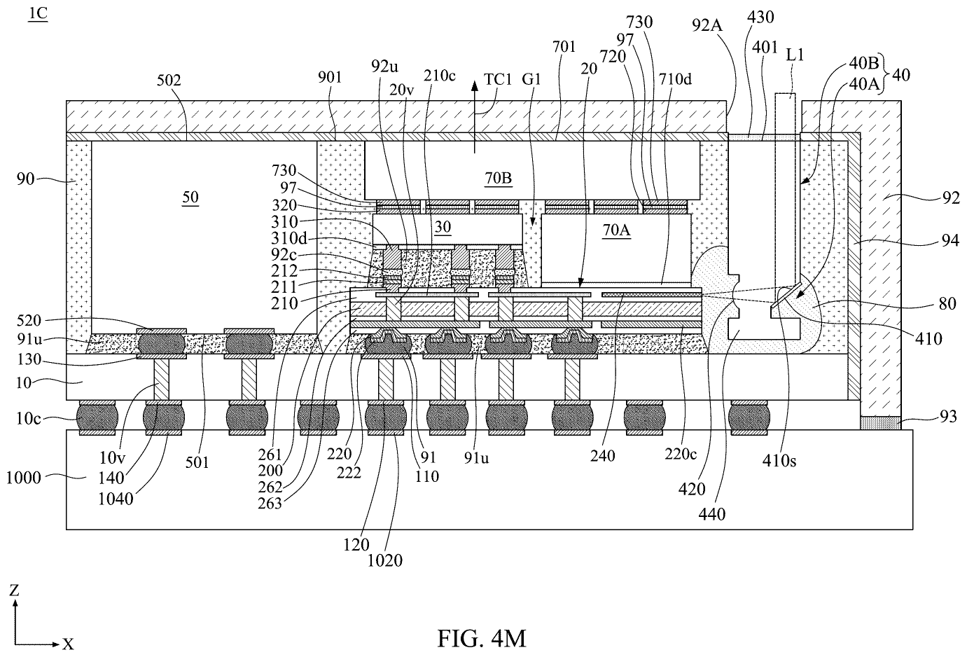

FIG. 4A, FIG. 4B, FIG. 4C, FIG. 4D, FIG. 4E, FIG. 4F, FIG. 4G, FIG. 4H, FIG. 4I, FIG. 4J, FIG. 4K, FIG. 4L, and FIG. 4M illustrate various stages of an exemplary method for manufacturing a package structure 1B in accordance with some embodiments of the present disclosure.

Referring to FIG. 4A, a wafer level reinforcement element 70B′ including pads 730 and metal layers 97A formed on a surface thereof may be provided. In some arrangements, a thickness of the metal layers 97A is less than a thickness of the pads 730. In some arrangements, the metal layers 97A may be or include a metal material having a relatively low melting point. In some arrangements, the melting point of the metal layers 97A is lower than the melting point of the pads 730. The melting point of the metal layers 97A may be lower than 260 °C, 200 °C, 150 °C, 130 °C, or 100 °C. The pads 730 may or include Au, Ag, Al, Cu, Ni, or an alloy thereof. The metal layers 97A may be or include gallium (Ga), indium (In), In—Sn alloy, or an alloy thereof.

Referring to FIG. 4B, a wafer level electronic component 30′ including a dielectric layer 310d and conductive pads 310 and 320 may be provided, and a wafer level reinforcement element 70A′ including a dielectric layer 710d may be provided. The conductive pads 310 may be referred to as vias or pillars.

Referring to FIG. 4C, a wafer level photonic component including a substrate layer 200A, conductive pads 210 and 220, barrier layers 212 and 222, conductive layers 210c, 220c, and 211, conductive vias 20v, an optical channel 240A, and dielectric layers 261, 262, and 263 may be provided, and electrical contacts 91 may be disposed on the conductive pads 220. The above wafer level structure may be disposed over a carrier 4100 with the electrical contacts 91 embedded in the gel layer 4200 on the carrier 4100. The carrier 4100 may be a rigid carrier and configured to support the wafer level photonic component, and the gel layer 4200 is configured to provide stress buffer and accommodating spaces for the electrical contacts 91. In some arrangements, a singulation operation may be performed on the wafer level electronic component 30′ to form a plurality of electronic components 30, a singulation operation may be performed on the wafer level reinforcement elements 70A′ to form a plurality of reinforcement elements 70A, and the electronic components 30 and the reinforcement elements 70A are disposed over and connected to the wafer level photonic component.

Referring to FIG. 4D, a singulation operation may be performed on the wafer level reinforcement elements 70B′ to form a plurality of reinforcement elements 70B, and the reinforcement elements 70B may be disposed over and connected to the electronic components 30 and the reinforcement elements 70A. In some arrangements, the metal layers 97A on the pads 730 may be connected to the conductive pads 320 and the pads 720 to connect the reinforcement elements 70B to the electronic components 30 and the reinforcement elements 70A. In some arrangements, a thermal treatment may be performed to melt the metal layers 97A and allow the melted metal layers 97A to form connection elements 97 each formed of an alloy layer or an IMC layer to bond the pad 730 to the conductive pads 320 and the pads 720. The thermal treatment may be performed under a temperature lower than 260 °C, 200 °C, 150 °C, 130 °C, or 100 °C. The as-formed connection element 97 may have a melting point higher than the melting point of the metal layers 97A, the melting point of a solder material, the melting point of the pad 720, the melting point of the pad 730, and/or the melting point of the conductive pad 320.

Referring to FIG. 4E, the structure illustrate in FIG. 4D may be disposed over a tape 4300, and a singulation operation may be performed to form a plurality of photonic components 20. The gel layer 4200 and the carrier 4100 may be removed.

Referring to FIG. 4F, the tape 4300 may be removed after the singulation operation. In some arrangements, each of the singulation structures illustrated in FIG. 4E may be disposed over and supported by a carrier or a tray. The reinforcement elements 70A and 70B provide a supporting force to increase the structural strength of the photonic component 20 so as to reduce warpage of the photonic component 20.

Referring to FIG. 4G and FIG. 4H, FIG. 4G shows a cross-section along a line 4G-4G′ in FIG. 4H. Electronic components 50 and 50M and the photonic components 20 may be connected to a wafer-level substrate 10A through electrical contacts 91.

Referring to FIG. 4I and FIG. 4J, FIG. 4I shows a cross-section along a line 4I-4I′ in FIG. 4J. Optical guiding components 40 may be connected to the photonic components 20 through connection structures 80. In some arrangements, a plurality of optical gels may be dispensed over the wafer-level substrate 10A and portions of the photonic components 20, the optical guiding components 40 may be disposed over and partially extending into the optical gels, and the a curing operation may be performed on the optical gels to form the connection structures 80. In some arrangements, the optical guiding component 40 may be formed by nanoimprint technology using sol-gel glass or a transparent polymer material. In some arrangements, the optical guiding component 40 may be formed providing a plurality of glass portions each having predetermined shapes followed by assembling these glass portions to each other. The predetermined shapes of the glass portions may be formed by etching.

Referring to FIG. 4K, an encapsulant 90A may be disposed or formed over the wafer-level substrate 10A to encapsulate the photonic components 20, the electronic components 50 and 50M, the optical guiding components 40, and the connection structures 80.

Referring to FIG. 4L, a grinding operation may be performed to partially remove the encapsulant 90A to expose surfaces of the optical guiding components 40, the electronic components 50 and 50M, and the reinforcement elements 70B (e.g. surfaces 401, 502, and 701) and to form a surface 901 of the encapsulant 90A that is substantially aligned with the surfaces 401, 502, and 701. Next, antireflective elements 430 may be formed on the surfaces 401 of the optical guiding components 40.

Still referring to FIG. 4L, after the antireflective elements 430 are formed, an optoelectronic inspection may be performed on the wafer-level structure illustrated in FIG. 4L by allowing optical signals from the optical channels 240 of the photonic components 20 to transmit from substantially horizontally to substantially vertically after passing through the optical guiding components 40 so as to optically couple to an optical inspection tool over the optical guiding components 40. The optoelectronic inspection may be or include a detection of an amount of optical coupling through vertical coupling. In some arrangements, an electrical inspection may be performed on the wafer-level structure illustrated in FIG. 4L by allowing electrical signals from the electronic component 50 to transmit to the electrical contacts 10c through the conductive vias 10v of the wafer-level substrate 10A so as to electrically couple to an electrical inspection tool. Therefore, the structural design as well as the manufacturing process thereof allows both the optoelectronic inspection and the electrical inspection to be performed on the wafer-level structure.

Referring to FIG. 4M, after the optoelectronic inspection and the electrical inspection are performed, a singulation operation may be performed on the wafer-level structure illustrated in FIG. 4L to form a plurality of singulated structures, the singulated structure may be connected to a substrate 1000 through the electrical contacts 10c, and a thermal cooling component 92 may be connected to the encapsulant 90 through a thermal conductive adhesive 94. As such, the package structure 1C illustrated in FIGS. 1C and 1D may be formed.

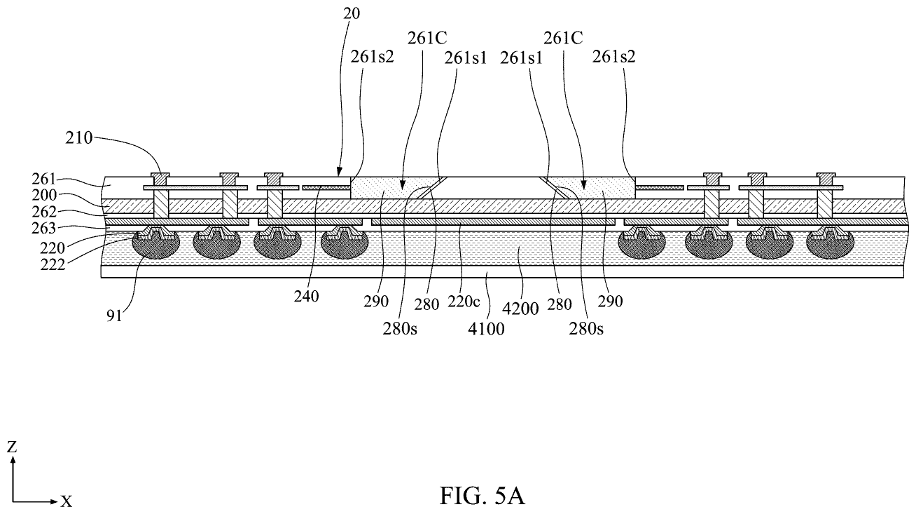

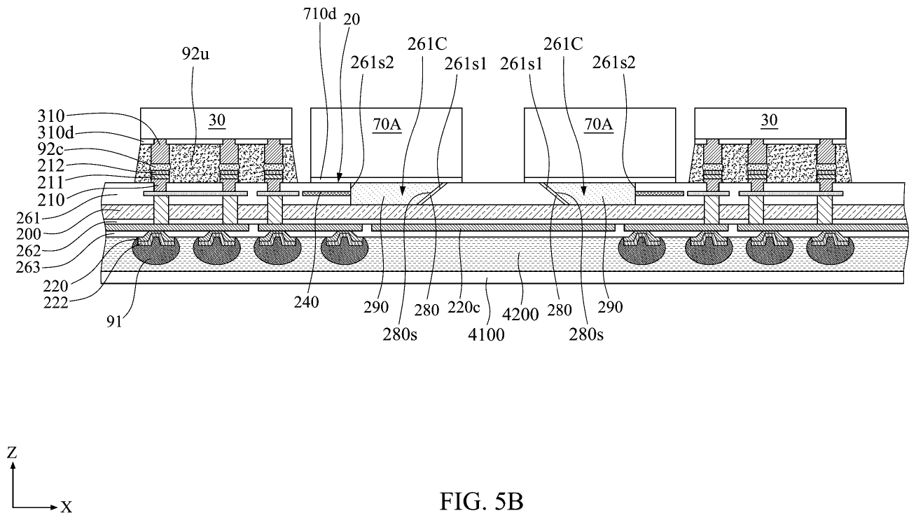

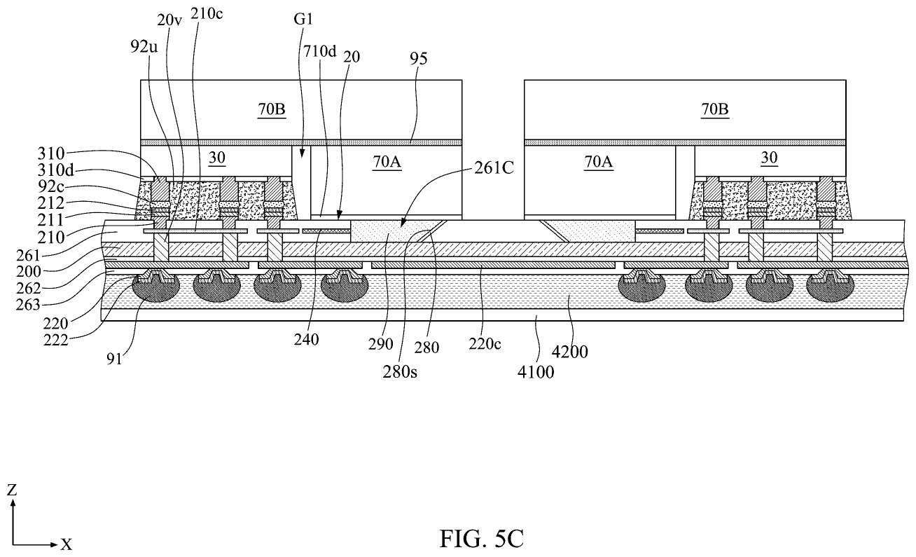

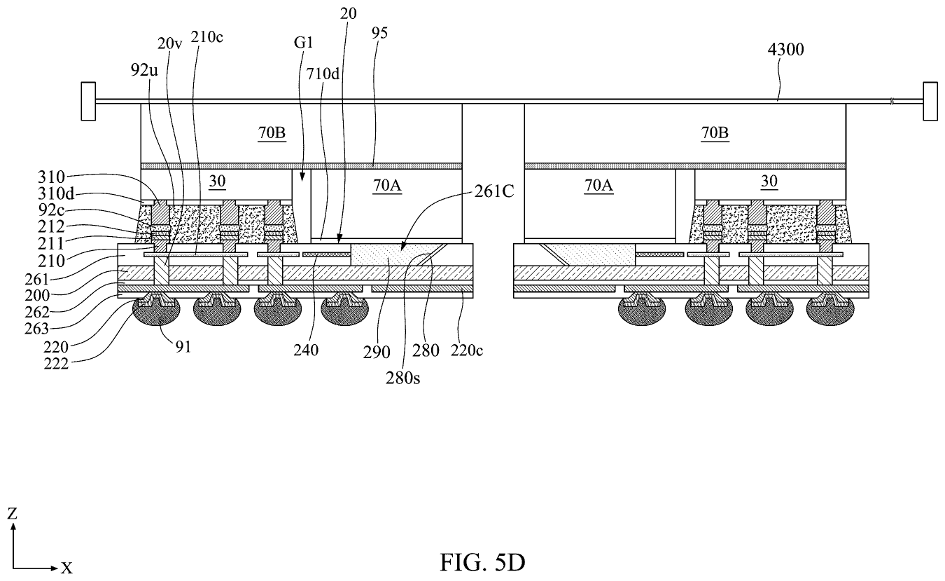

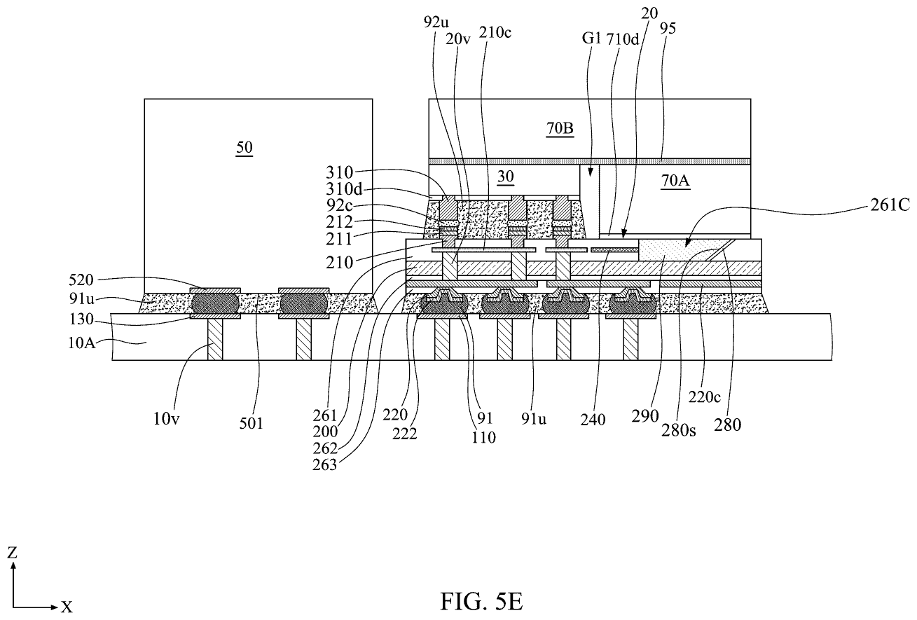

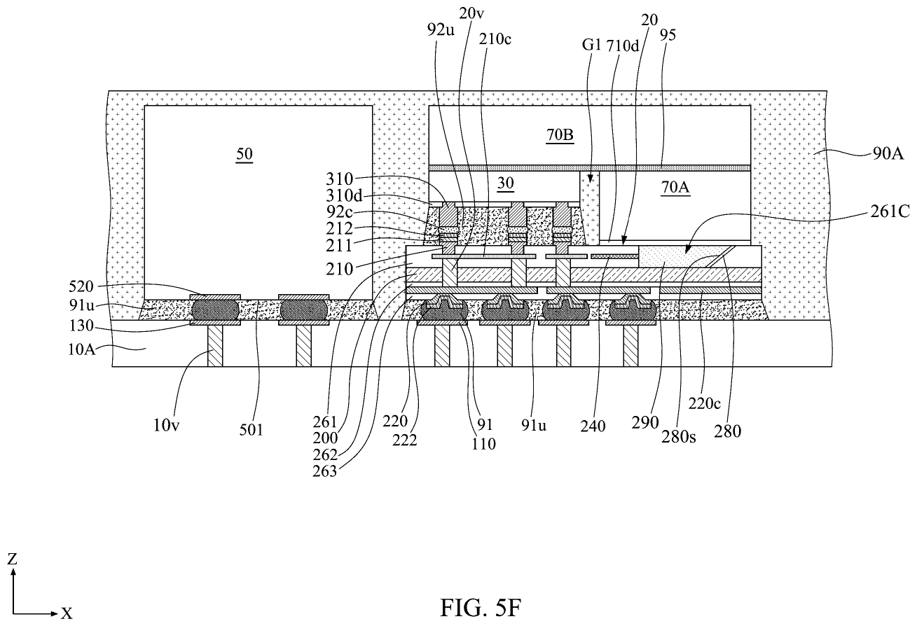

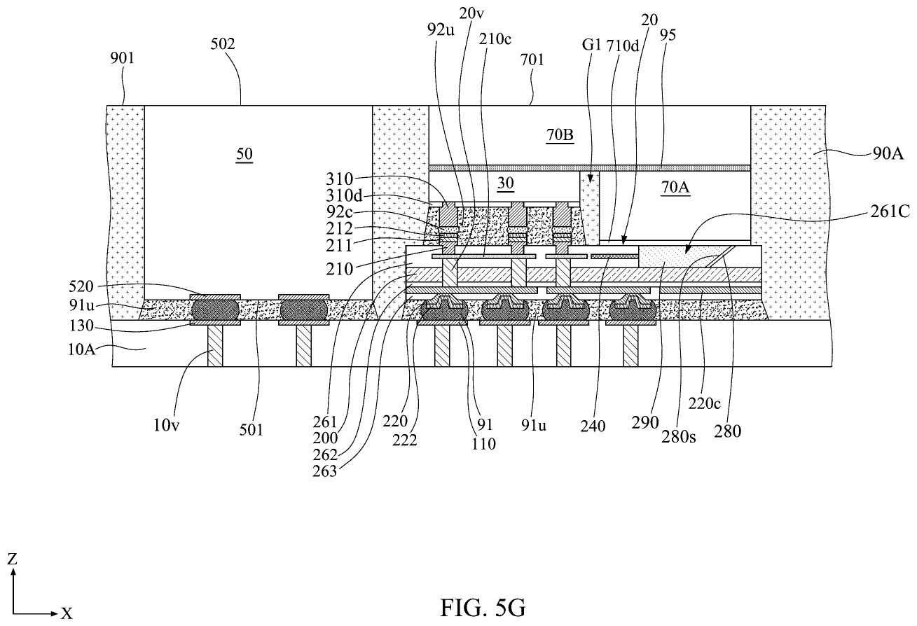

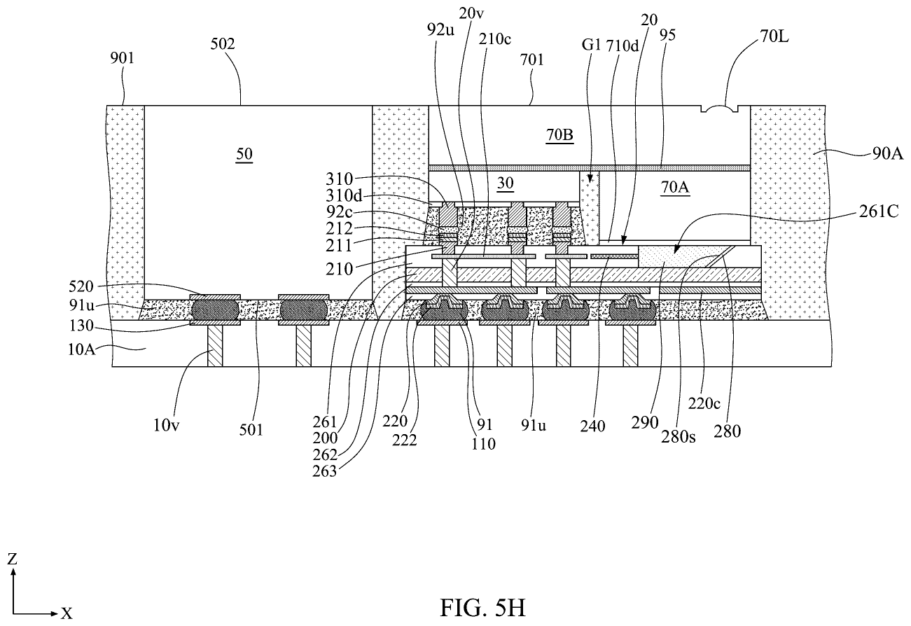

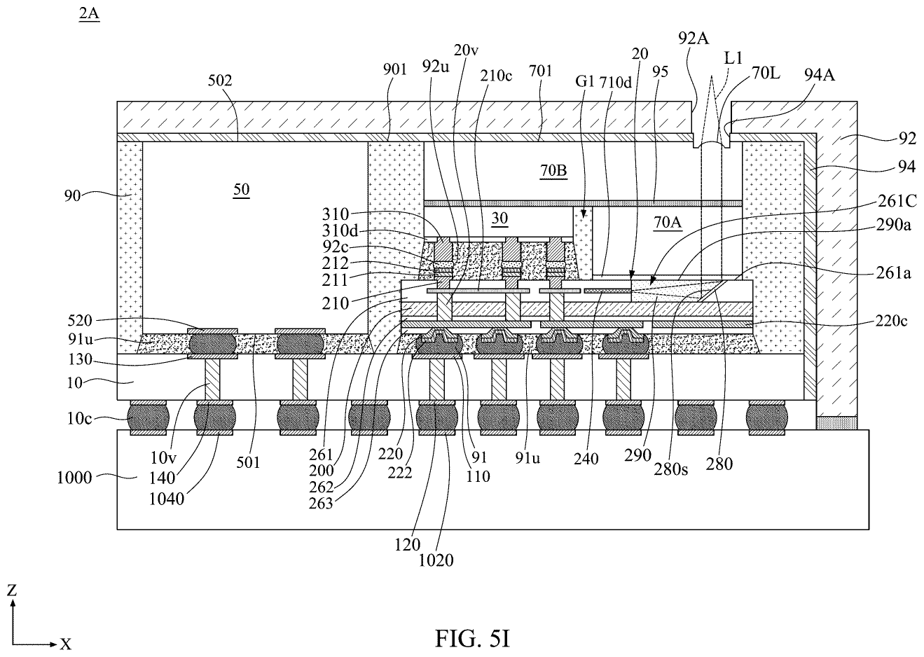

FIG. 5A, FIG. 5B, FIG. 5C, FIG. 5D, FIG. 5E, FIG. 5F, FIG. 5G, FIG. 5H, and FIG. 5I illustrate various stages of an exemplary method for manufacturing a package structure 2A in accordance with some arrangements of the present disclosure.

Referring to FIG. 5A, a wafer level photonic component including a substrate layer 200A, conductive pads 210 and 220, conductive layers 210c, 220c, and 211, conductive vias 20v, an optical channel 240A, and dielectric layers 261, 262, and 263 may be provided, and electrical contacts 91 may be disposed on the conductive pads 220. The above wafer level structure may be disposed over a carrier 4100 with the electrical contacts 91 embedded in the gel layer 4200 on the carrier 4100. The carrier 4100 may be a rigid carrier and configured to support the wafer level photonic component, and the gel layer 4200 is configured to provide stress buffer and accommodating spaces for the electrical contacts 91.

Still referring to FIG. 5A, recesses 261C may be formed within the dielectric layer 261d, reflective elements 280 may be formed on lateral surfaces 261s1 in the recesses 261C, and optical coupling portions 290 may be formed in the recesses 261C. In some arrangements, the recesses 261C are formed by etching. In some arrangements, the reflective elements 280 may be formed by depositing or plating metal layers on the lateral surfaces 261s1 in the recesses 261C. In some arrangements, the optical coupling portions 290 may be formed by dispensing optical gels in the recesses 261C followed by curing the optical gels. The optical gels may have a relatively high flowability so as to allow the optical gels to have substantially planar top surfaces. In some arrangements, the optical coupling portions may be formed by depositing a dielectric material in the recesses 261C to form dielectric layers in the recesses 261C followed by performing a planarization operation to remove portions of the dielectric layers to form the optical coupling portions 290 having top surfaces substantially aligned with the top surface of the dielectric layer 261.

Referring to FIG. 5B, barrier layers 212 and 222 may be formed on the conductive pads 210, a singulation operation may be performed on the wafer level electronic component 30′ to form a plurality of electronic components 30, a singulation operation may be performed on the wafer level reinforcement elements 70A′ to form a plurality of reinforcement elements 70A, and the electronic components 30 and the reinforcement elements 70A are disposed over and connected to the wafer level photonic component.

Referring to FIG. 5C, operations similar to those illustrated in FIG. 4D may be performed to connect a plurality of reinforcement elements 70B to the electronic components 30 and the reinforcement elements 70A.

Referring to FIG. 5D, the structure illustrate in FIG. 5C may be disposed over a tape 4300, and a singulation operation may be performed to form a plurality of photonic components 20. The gel layer 4200 and the carrier 4100 may be removed.

Referring to FIG. 5E, operations similar to those illustrated in FIGS. 4G and 4H may be performed to connect electronic components 50 and 50M and the photonic components 20 to a wafer-level substrate 10A through electrical contacts 91.

Referring to FIG. 5F, operations similar to those illustrated in FIG. 4K may be performed to form an encapsulant 90A over the wafer-level substrate 10A to encapsulate the photonic components 20 and the electronic components 50 and 50M.

Referring to FIG. 5G, operations similar to those illustrated in FIG. 4L may be performed to grinding operation to partially remove the encapsulant 90A to expose surfaces of the electronic components 50 and 50M and the reinforcement elements 70B, and an optoelectronic inspection and an electrical inspection may be performed on the wafer-level structure.

Referring to FIG. 5H, lenses 70L may be formed on surfaces 701 of the reinforcement elements 70B. In some arrangements, the lenses 70L may be formed by etching.

Referring to FIG. 5I, operations similar to those illustrated in FIG. 4M may be performed to form a plurality of singulated structures, connect the singulated structure to a substrate 1000 through the electrical contacts 10c, and connect a thermal cooling component 92 to the encapsulant 90 through a thermal conductive adhesive 94. As such, the package structure 2A illustrated in FIGS. 2A and 2B may be formed.

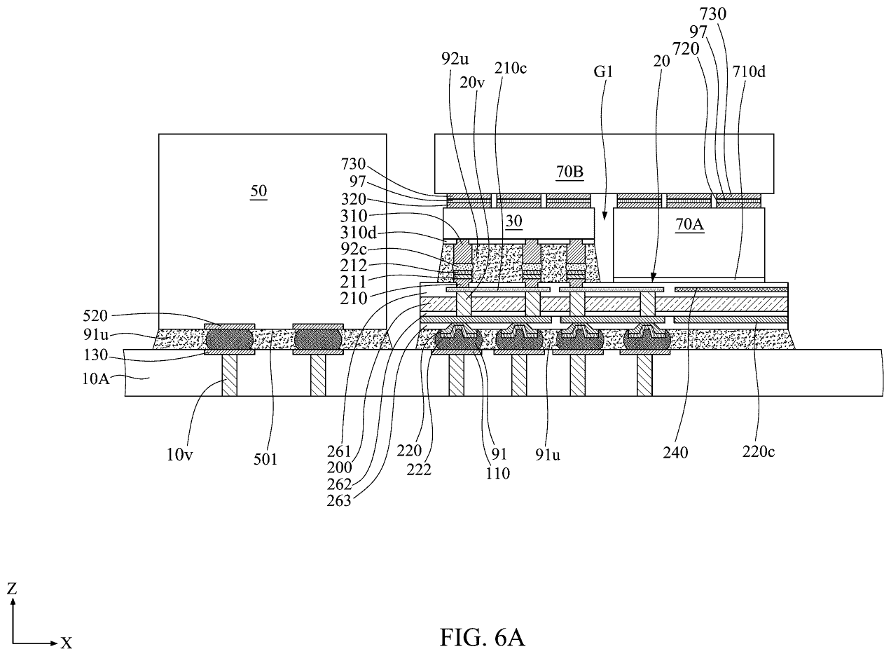

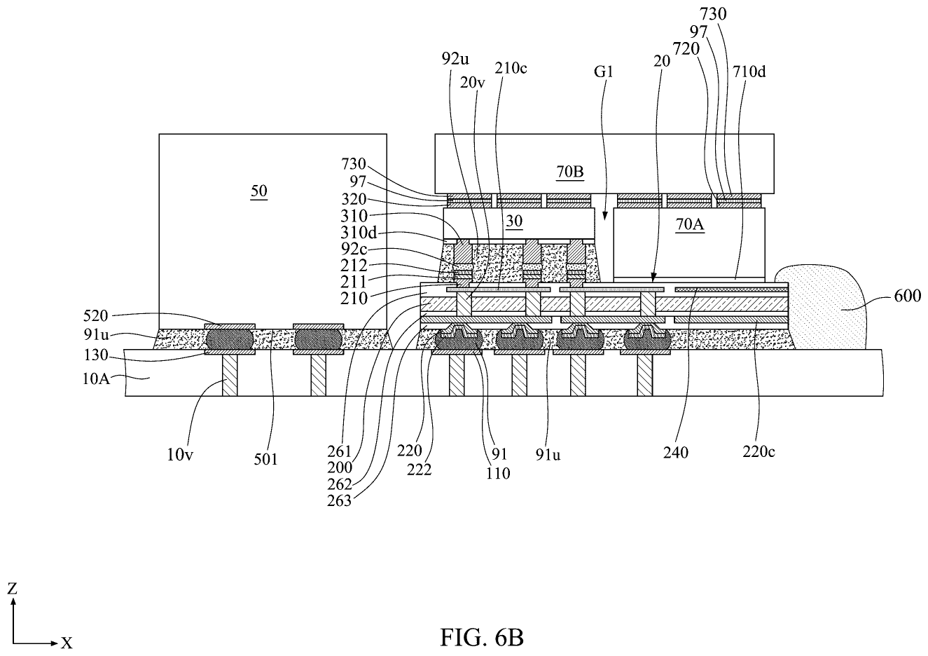

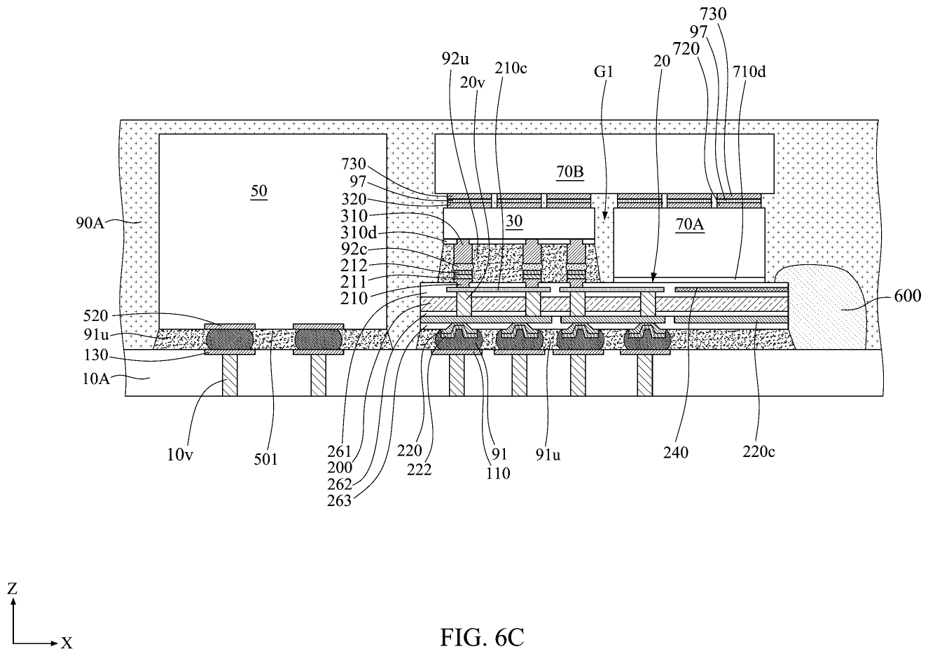

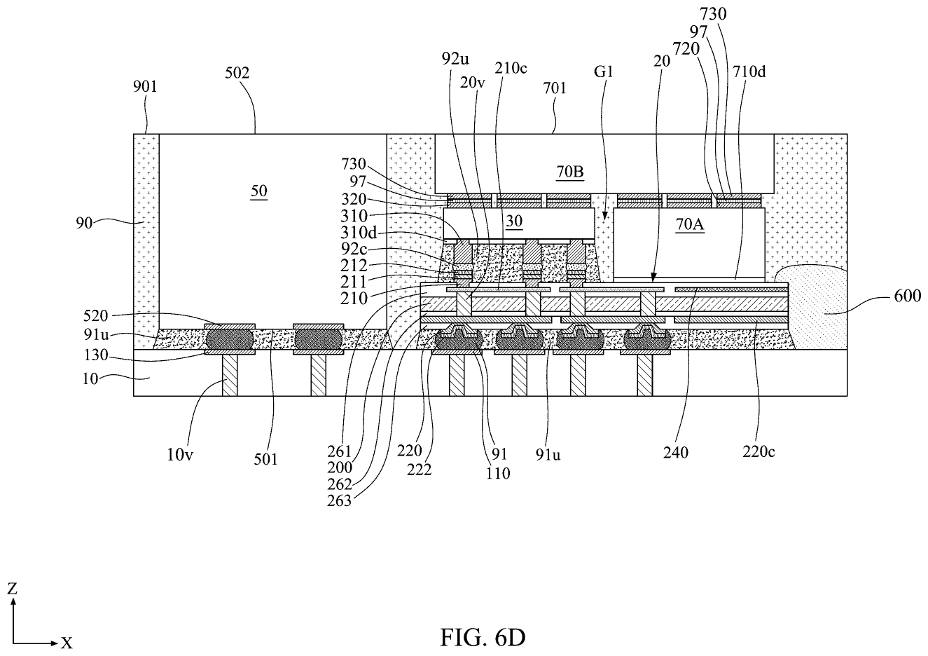

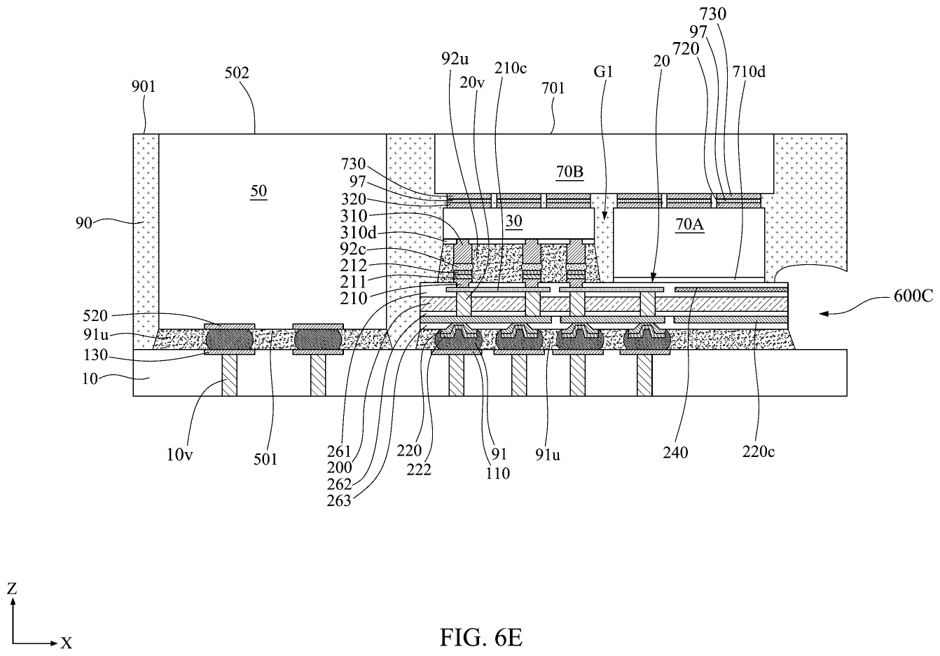

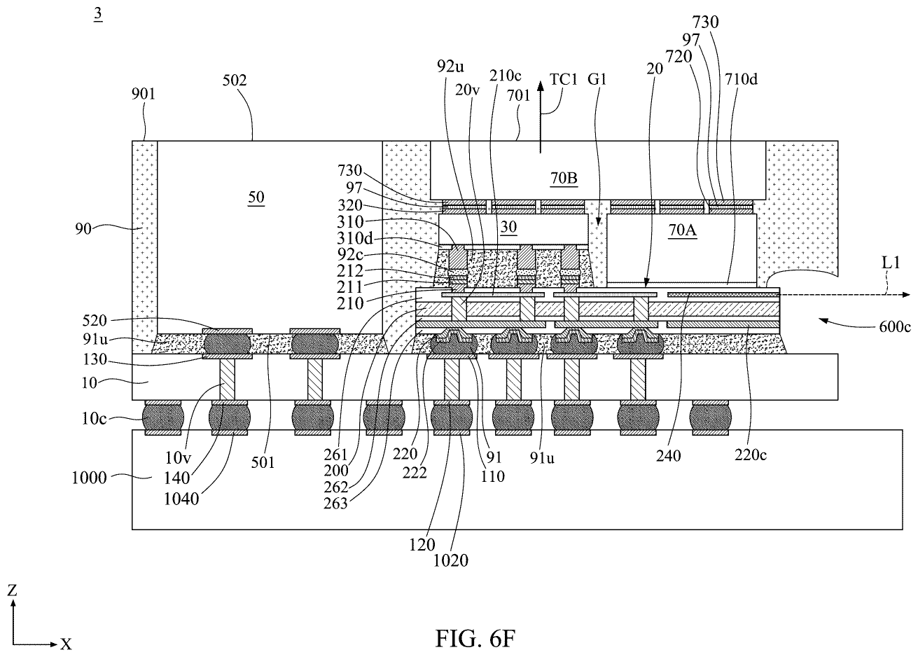

FIG. 6A, FIG. 6B, FIG. 6C, FIG. 6D, FIG. 6E, and FIG. 6F illustrate various stages of an exemplary method for manufacturing a package structure 3 in accordance with some embodiments of the present disclosure.

Referring to FIG. 6A, operation similar to those illustrated in FIGS. 4A to 4H may be performed to connect electronic components 50 and 50M and photonic components 20 to a wafer-level substrate 10A through electrical contacts 91.

Referring to FIG. 6B, sacrificial structures 600 may be disposed over the wafer-level substrate 10A to cover the optical channels 240 of the photonic components 20. In some arrangements, the sacrificial structures 600 include gels.

Referring to FIG. 6C, operations similar to those illustrated in FIG. 4K may be performed to form an encapsulant 90A over the wafer-level substrate 10A to encapsulate the photonic components 20, the electronic components 50 and 50M, and the sacrificial structures 600.

Referring to FIG. 6D, operations similar to those illustrated in FIG. 4L may be performed to grinding operation to partially remove the encapsulant 90A to expose surfaces of the electronic components 50 and 50M, and the reinforcement elements 70B, and an singulation operation may be performed to cut through the sacrificial structures 600 to form a plurality of singulated structures.

Referring to FIG. 6E, the sacrificial structures 600 of the singulated structure may be removed to form a recess 600C that exposes the optical channel 240.

Referring to FIG. 6F, the singulated structure illustrated in FIG. 6E may be connected to a substrate 1000 through electrical contacts 10c. As such, the package structure 3 illustrated in FIG. 3 may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a photonic component;
an optical guiding component disposed external to the photonic component and configured to change a transmission direction of an optical signal from the photonic component; and
a connection structure connecting the optical guiding component to the photonic component and configured to reduce scattering of the optical signal during transmission.

2. The package structure as claimed in claim 1, wherein the optical guiding component is disposed at a lateral side of the photonic component and configured to switch the transmission direction between a substantially horizontal direction and a substantially vertical direction.

3. The package structure as claimed in claim 1, wherein the optical guiding component comprises a reflective surface configured to reflect the optical signal to change the transmission direction.

4. The package structure as claimed in claim 3, wherein the optical guiding component comprises a reflective layer defining the reflective surface.

5. The package structure as claimed in claim 1, wherein the optical guiding component comprises a switch portion comprising a lens facing an optical channel of the photonic component and a transmission portion configured to transmit the optical signal from the switch portion upwardly.

6. The package structure as claimed in claim 5, wherein the switch portion is embedded in the connection structure.

7. The package structure as claimed in claim 5, wherein the switch portion further comprises a reflective element configured to reflect the optical signal transmitted through the lens.

8. The package structure as claimed in claim 5, further comprising an encapsulant encapsulating the photonic component, the optical guiding component, and the connection structure, wherein a surface of the optical guiding component is exposed by the encapsulant.

9. The package structure as claimed in claim 8, wherein the transmission portion comprises an antireflective element on the surface of the optical guiding component.

10. The package structure as claimed in claim 1, wherein the connection structure comprises an optical gel and having an irregular profile from a cross-sectional view perspective.

11. A package structure, comprising:
a photonic component comprising an optical channel;
an optical guiding component; and
an encapsulant encapsulating the photonic component and the optical guiding component, wherein the optical guiding component is configured to direct an optical signal from the optical channel to transmit along an optical path embedded in the encapsulant and emit out of the encapsulant.

12. The package structure as claimed in claim 11, wherein the photonic component comprises a dielectric layer covering the optical channel, and a portion of the optical channel is exposed by the dielectric layer and contacts the optical guiding component.

13. The package structure as claimed in claim 12, wherein the optical guiding component comprises an optical coupling portion and a reflective layer in a recess defined by the dielectric layer.

14. The package structure as claimed in claim 13, wherein a reflective surface defined by the reflective layer is inclined with respect to a top surface of the dielectric layer.

15. The package structure as claimed in claim 11, further comprising a thermal cooling component covering the encapsulant and a thermal conductive adhesive between the encapsulant and the thermal cooling component, wherein the thermal conductive adhesive is partially exposed by an opening of the thermal cooling component from a top view perspective.

16. The package structure as claimed in claim 11, further comprising:
a substrate;
a plurality of the photonic components disposed over the substrate;
a plurality of the optical guiding components optically coupled to the photonic components; and
a plurality of optical islands disposed over the substrate and connecting the optical guiding components to the photonic components.

17. An optical guiding element, comprising:
a reflective element fixedly coupled to an optical channel of a photonic component via an integrated alignment structure, wherein the optical guiding element is configured to redirect, concentrate, or diffuse an optical signal based on a predetermined distribution profile of the optical guiding element.

18. The optical guiding element as claimed in claim 17, wherein the integrated alignment structure comprises an optical fastener and a lens having different refractive indexes, and the reflective element is disposed external to the photonic component and spaced apart from the optical channel of the photonic component by the optical fastener and the lens.

19. The optical guiding element as claimed in claim 17, wherein the reflective element is embedded in the photonic component.

20. The optical guiding element as claimed in claim 19, wherein the integrated alignment structure comprises an optical laminate over the reflective element and connecting a dummy die to the photonic component.
